(19) United States
(12) Patent Application Publication
(10) Pub. No.: US 2025/0176378 A1
(43) Pub. Date: May 29, 2025

(54) DISPLAY DEVICE

(71) Applicant: Samsung Display Co., Ltd., Yongin-Si (KR)

(72) Inventors: Dong Hyeon JANG, Yongin-si (KR); Min Kyung PARK, Yongin-si (KR); Seung Woo SUNG, Yongin-si (KR); Young Soo YOON, Yongin-si (KR); Bong Won LEE, Yongin-si (KR); Won Se LEE, Yongin-si (KR); Su Kyo JUNG, Yongin-si (KR); Seung Han JO, Yongin-si (KR); Min Hee CHOI, Yongin-si (KR); Sun Baek HONG, Yongin-si (KR)

(21) Appl. No.: 18/743,496

(22) Filed: Jun. 14, 2024

(30) Foreign Application Priority Data
Nov. 27, 2023 (KR) 10-2023-0166868

(51) Int. Cl. H10K 59/131; H10K 59/80

(52) U.S. Cl. CPC H10K 59/131; H10K 59/873

(57) ABSTRACT

A display device includes a plurality of pixels disposed in a display area, a (1-1)-th constant voltage electrode disposed in a peripheral area, a (2-1)-th constant voltage electrode disposed in the peripheral area to be spaced apart from the (1-1)-th constant voltage electrode, a connection electrode electrically connecting the (1-1)-th constant voltage electrode and the (2-1)-th constant voltage electrode, and disposed on a layer different from the (1-1)-th constant voltage electrode and the (2-1)-th constant voltage electrode in a cross-sectional view, a (1-1)-th cladding layer covering at least a (1-1)-th side surface portion of the (1-1)-th constant voltage electrode facing the (2-1)-th constant voltage electrode, and a (1-2)-th constant voltage electrode disposed on an upper surface of the (1-1)-th cladding layer and directly contacting at least a portion of an upper surface of the (1-1)-th constant voltage electrode.

This application claims priority to Korean Patent Application No. 10-2023-0166868, filed on Nov. 27, 2023, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

A display device may include a plurality of pixels disposed in a display area, an electrode disposed in a peripheral area for providing an electrical signal to the plurality of pixels, and a line electrically connecting the plurality of pixels and the electrode.

When a surface of a conductive layer forming the electrode is damaged, reliability of the electrode may be deteriorated. Accordingly, display quality of the display device may be deteriorated.

### SUMMARY

An object of the disclosure is to provide a display device including an electrode with improved reliability.

According to embodiments of the disclosure, a display device includes a plurality of pixels disposed in a display area, a (1-1)-th constant voltage electrode disposed in a peripheral area, a (2-1)-th constant voltage electrode disposed in the peripheral area to be spaced apart from the (1-1)-th constant voltage electrode, a connection electrode electrically connecting the (1-1)-th constant voltage electrode and the (2-1)-th constant voltage electrode, and disposed on a layer different from the (1-1)-th constant voltage electrode and the (2-1)-th constant voltage electrode in a cross-sectional view, a (1-1)-th cladding layer covering at least a (1-1)-th side surface portion of the (1-1)-th constant voltage electrode facing the (2-1)-th constant voltage electrode, and a (1-2)-th constant voltage electrode disposed on an upper surface of the (1-1)-th cladding layer and directly contacting at least a portion of an upper surface of the (1-1)-th constant voltage electrode.

In an embodiment, the display device may further include a (1-2)-th cladding layer covering at least a (1-2)-th side surface portion of the (1-2)-th constant voltage electrode disposed on the (1-1)-th cladding layer.

In an embodiment, the display device may further include an organic cover layer entirely covering the (1-2)-th cladding layer.

In an embodiment, the (1-1)-th cladding layer, the (1-2)-th cladding layer, and the organic cover layer may form a first dam structure, and the first dam structure may surround the display area in a plan view.

In an embodiment, the display device may further include a second dam structure disposed on the (1-1)-th constant voltage electrode in a cross-sectional view, and the second dam structure may be disposed between the display area and the first dam structure to surround the display area in a plan view.

In an embodiment, the (1-2)-th constant voltage electrode may be interposed between the second dam structure and the (1-1)-th constant voltage electrode in a cross-sectional view.

In an embodiment, the display device may further include a (2-1)-th cladding layer covering at least a (2-1)-th side surface portion f of the (2-1)-th constant voltage electrode acing the (1-1)-th constant voltage electrode, and a (2-2)-th constant voltage electrode disposed on an upper surface of the (2-1)-th cladding layer, and directly contacting at least a portion of an upper surface of the (2-1)-th constant voltage electrode.

In an embodiment, the (2-1)-th cladding layer may entirely cover the side surface portion of the (2-1)-th constant voltage electrode.

In an embodiment, the (2-1)-th cladding layer may include an opening exposing at least a portion of an upper surface of the (2-1)-th constant voltage electrode, and the (2-2)-th constant voltage electrode may directly contacts the upper surface of the (2-1)-th constant voltage electrode exposed by the opening.

In an embodiment, the opening may be provided in plural.

In an embodiment, the display device may further include an encapsulation layer entirely covering the plurality of pixels disposed in in the display area, and the encapsulation layer may include a first inorganic encapsulation layer, a second inorganic encapsulation layer, and an organic encapsulation layer interposed between the first inorganic encapsulation layer and the second inorganic encapsulation layer.

In an embodiment, the first inorganic encapsulation layer and the second inorganic encapsulation layer may directly contact each other in an area between the (1-1)-th constant voltage electrode and the (2-1)-th constant voltage electrode in a plan view.

In an embodiment, a CVD area in which an organic insulating material is not interposed between the connection electrode and the first inorganic encapsulation layer may be disposed in an area overlapping the connection electrode.

According to embodiments of the disclosure, a display device may include a plurality of pixels disposed in a display area, a (1-1)-th constant voltage electrode disposed in a peripheral area, a (2-1)-th constant voltage electrode disposed in the peripheral area to be spaced apart from the (1-1)-th constant voltage electrode, a connection electrode electrically connecting the (1-1)-th constant voltage electrode and the (2-1)-th constant voltage electrode, and disposed on a layer different from the (1-1)-th constant voltage electrode and the (2-1)-th constant voltage electrode in a cross-sectional view, a (1-1)-th cladding layer covering at least a (1-1)-th side surface portion of the (1-1)-th constant voltage electrode facing the (2-1)-th constant voltage electrode, a (1-2)-th constant voltage electrode disposed on an upper surface of the (1-1)-th cladding layer and directly contacting at least a portion of an upper surface of the (1-1)-th constant voltage electrode, a (1-2)-th cladding layer covering at least a (1-2)-th side surface portion of the (1-2)-th constant voltage electrode disposed on the (1-1)-th cladding layer, and a (1-3)-th constant voltage electrode disposed on an upper surface of the (1-2)-th cladding layer and directly contacting at least a portion of an upper surface of the (1-2)-th constant voltage electrode.

In an embodiment, the display device may further include an organic cover layer entirely covering the (1-2)-th cladding layer.

In an embodiment, the (1-2)-th cladding layer and the organic cover layer may form a first dam structure, and in a plan view, the first dam structure may surround the display area.

In an embodiment, the display device may further include a (2-1)-th cladding layer covering at least a (2-1)-th side surface portion of the (2-1)-th constant voltage electrode facing the (1-2)-th constant voltage electrode, and a (2-2)-th constant voltage electrode disposed on an upper surface of the (2-1)-th cladding layer and directly contacting at least a portion of an upper surface of the (2-1)-th constant voltage electrode.

In an embodiment, the display device may further include an encapsulation layer entirely disposed on the plurality of pixels disposed in the display area, and the encapsulation layer may include a first inorganic encapsulation layer, a second inorganic encapsulation layer, and an organic encapsulation layer interposed between the first inorganic encapsulation layer and the second inorganic encapsulation layer.

In an embodiment, the first inorganic encapsulation layer and the second inorganic encapsulation layer may directly contact each other in an area between the (1-1)-th constant voltage electrode and the (2-1)-th constant voltage electrode in a plan view.

In an embodiment, a CVD area in which an organic insulating material is not interposed between the connection electrode and the first inorganic encapsulation layer may be disposed in an area overlapping the connection electrode.

In the display device according to embodiments of the disclosure, the first constant voltage electrode may include the (1-1)-th constant voltage electrode and the (1-2)-th constant voltage electrode sequentially stacked. Here, the (1-1)-th side surface portion of the (1-1)-th constant voltage electrode may be covered by the (1-1)-th cladding layer. Accordingly, during a forming process of forming the (1-2)-th constant voltage electrode on the (1-1)-th constant voltage electrode, the (1-1)-th cladding layer may serve to protect the (1-1)-th side surface portion of the (1-1)-th constant voltage electrode. That is, damage to the (1-1)-th side surface portion, which is relatively vulnerable to damage, may be effectively prevented.

In the display device according to embodiments of the disclosure, the first constant voltage electrode may include the (1-1)-th constant voltage electrode, the (1-2)-th constant voltage electrode, and the (1-3)-th constant voltage electrode sequentially stacked. Here, the (1-2)-th side surface portion of the (1-2)-th constant voltage electrode may be covered by the (1-2)-th cladding layer. Accordingly, during a forming process of forming the (1-3)-th constant voltage electrode on the (1-2)-th constant voltage electrode, the (1-2)-th cladding layer may serve to protect the (1-2)-th side surface portion of the (1-2)-th constant voltage electrode. That is, damage to the (1-2)-th side surface portion, which is relatively vulnerable to damage, may be effectively prevented.

### BRIEF DESCRIPTION OF THE DRAWINGS

The above and other features of the disclosure will become more apparent by describing in further detail embodiments thereof with reference to the accompanying drawings, in which:

FIG. 1A is a diagram illustrating a display device according to embodiments of the disclosure;

FIG. 1B is a circuit diagram illustrating a pixel according to embodiments of the disclosure;

FIGS. 2 and 3 are diagrams illustrating a structure of a pixel according to an embodiment of the disclosure;

FIG. 4 is an enlarged view of an area A of FIG. 1A and is a view illustrating a constant voltage electrode according to an embodiment of the disclosure;

FIGS. 5, 6, 7, 8, 9, 10A, 10B, 11A, 11B, 12, 13, 14, 15, 16 and 17 are diagrams illustrating the constant voltage electrode of FIG. 4;

FIGS. 18 and 19 are diagrams illustrating a structure of a pixel according to another embodiment of the disclosure;

FIG. 20 is an enlarged view of the area A of FIG. 1A and is a view illustrating a constant voltage electrode according to another embodiment of the disclosure; and

FIGS. 21, 22, 23A, 23B, 24,25, 26, 27, 28A, 28B, 29A, 29B, 30, 31, 32, 33, 34 and 35 are diagrams illustrating the constant voltage electrode of FIG. 20.

### DETAILED DESCRIPTION OF THE EMBODIMENT

Hereinafter, a preferred embodiment according to the disclosure is described in detail with reference to the accompanying drawings. It should be noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiment described herein. However, the embodiment described herein is provided to describe in detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

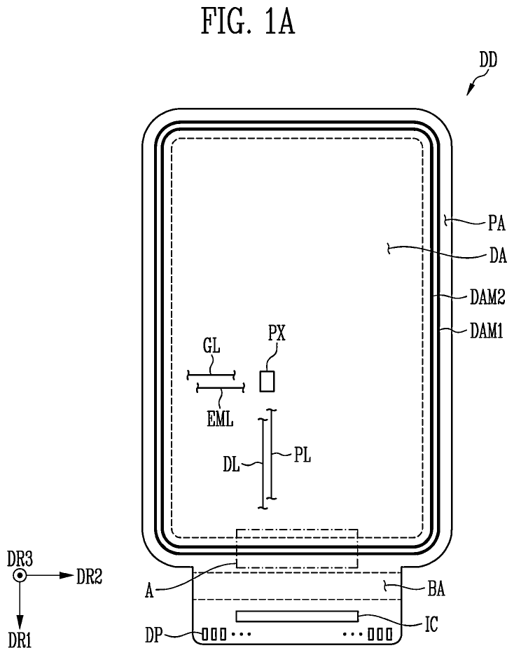

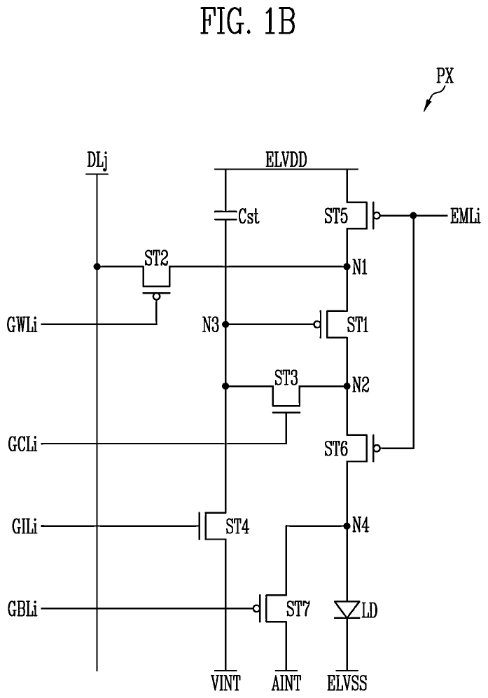

FIG. 1A is a diagram illustrating a display device according to embodiments of the disclosure.

Referring to FIG. 1A, the display device DD may include a display area DA and a peripheral area PA surrounding at least one side of the display area DA.

A pixel PX and a plurality of lines may be disposed in the display area DA. For example, the plurality of lines may include a scan signal line GL, an emission control signal line EML, a data line DL, and a power voltage line PL.

The pixel PX may receive an electrical signal from the plurality of lines. The pixel PX may emit light based on the electrical signal. Accordingly, an image may be displayed in the display area DA.

The scan signal line GL may transmit a scan signal to the pixel PX. For example, the scan signal line GL may extend in a second direction DR2 to electrically connect a scan driving circuit unit (not shown) disposed in the peripheral area PA and the pixel PX.

The emission control signal line EML may transmit an emission control signal to the pixel PX. For example, the emission control signal line EML may extend in the second direction DR2 to electrically connect an emission control circuit unit (not shown) disposed in the peripheral area PA and the pixel PX.

The data line DL may transmit a data voltage to the pixel PX. For example, the data line DL may extend in a first direction DR1 crossing the second direction DR2 to electrically connect an integrated circuit chip IC disposed in the peripheral area PA and the pixel PX.

The power voltage line PL may transmit a power voltage to the pixel PX. For example, the power voltage line PL may extend in the first direction DR1 to electrically connect a constant voltage electrode disposed in the peripheral area PA and the pixel PX.

In an embodiment, the power voltage line PL may include a vertical power voltage line extending in the first direction DR1 and a horizontal power voltage line extending in the second direction DR2 and electrically connected to the vertical power voltage line. In this case, the power voltage line PL may have a mesh shape disposed in the display area DA.

In FIG. 1A, for convenience of description, one of the pixel PX, the scan signal line GL, the emission control signal line EML, the data line DL, and the power voltage line PL is shown, but the pixel PX, the scan signal line GL, the emission control signal line EML, the data line DL, and the power voltage line PL may be provided in plural numbers.

A first dam structure DAM1, a second dam structure DAM2, the integrated circuit chip IC, and a pad unit DP may be disposed in the peripheral area PA. In addition, various circuit units (for example, a scan driving circuit unit, an emission control circuit unit, and the like), an electrode (for example, a constant voltage electrode), and lines, which are not shown in FIG. 1A may be disposed in the peripheral area PA.

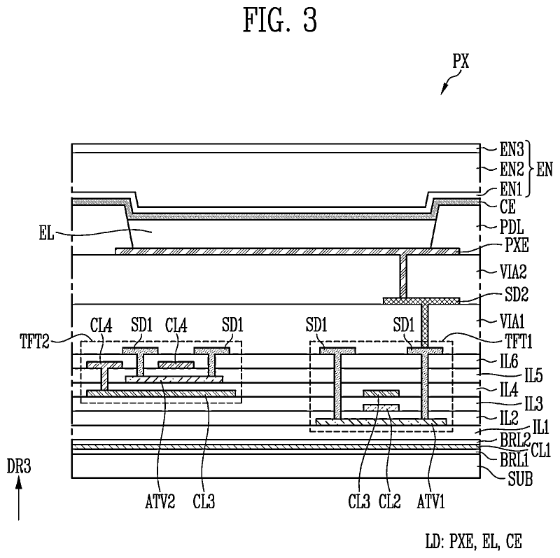

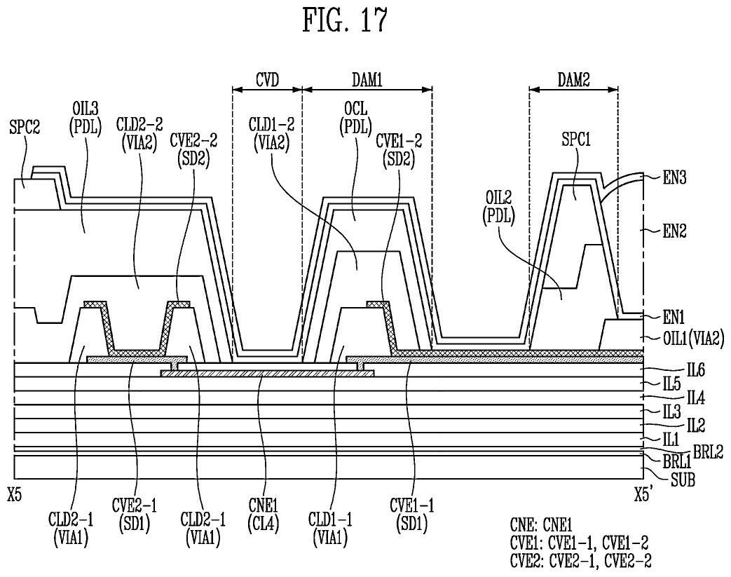

The first dam structure DAM1 may completely surround the display area DA. The second dam structure DAM2 may completely surround the display area DA and disposed between the first dam structure DAM1 and the display area DA. Each of the first dam structure DAM1 and the second dam structure DAM2 may have a sufficient height in a third direction DR3 crossing the first direction DR1 and the second direction DR2. Each of the first dam structure DAM1 and the second dam structure DAM2 may serve to block an organic encapsulation layer EN2 constituting an encapsulation layer EN of FIG. 3 covering the pixel PX. This is described later with reference to FIGS. 17 and 35.

In an embodiment, the peripheral area PA may include a bending area BA. At least a portion of the display device DD may be bent in the bending area BA. Accordingly, the integrated circuit chip IC and the pad unit DP may be disposed on a rear surface of the display device DD.

The integrated circuit chip IC may provide various electrical signals to the pixel PX. For example, the integrated circuit chip IC may provide a data voltage to the pixel PX.

The pad unit DP may be connected to an external electronic device (not shown) and may receive various electrical signals from the electronic device. In this case, the pad unit DP may transmit the electrical signal received from the electronic device to the pixel PX and/or a circuit unit through various lines and/or electrodes not shown in FIG. 1A.

FIG. 1B is a circuit diagram illustrating a pixel according to embodiments of the disclosure. In FIG. 1B, a pixel PX disposed in an i-th pixel row and a j-th pixel column among a plurality of pixels PX provided in the display area DA of FIG. 1A is shown as an example. Here, each of i and j is a natural number.

Referring to FIG. 1B, the pixel PX may include at least one transistor and at least one capacitor. For example, the pixel PX may include first to seventh transistors ST1, ST2, ST3, ST4, ST5, ST6, and ST7 and a storage capacitor Cst. However, this is exemplary, and those skilled in the art will be able to design a pixel PX including more or fewer transistors and/or more or fewer capacitors as needed. Hereinafter, a circuit in which some transistors ST1, ST2, ST5, ST6, and ST7 among the transistors ST1, ST2, ST3, ST4, ST5, ST6, and ST7 are P-type (PMOS) transistors and some other transistors ST3 and ST4 are N-type (NMOS) transistors is described as an example. However, those skilled in the art will be able to design a circuit including only an N-type transistor, a circuit including only a P-type transistor, or a circuit including various combinations of a P-type transistor and an N-type transistor by varying a polarity of a voltage applied to a gate electrode. Here, the P-type transistor collectively refers to a transistor in which a current amount increases when a voltage difference between a gate electrode and a source electrode increases in a negative direction, and the N-type transistor collectively refers to a transistor in which a current amount increases when a voltage difference between a gate electrode and a source electrode increases in a positive direction. A transistor may be implemented in various forms such as a thin film transistor (TFT), a field effect transistor (FET), and a bipolar junction transistor (BJT).

A first electrode of the first transistor ST1 (driving transistor) may be connected to a first node N1, a second electrode may be connected to a second node N2, and a gate electrode may be connected to a third node N3. The first transistor ST1 may control a driving current amount flowing from a first power voltage ELVDD to a second power voltage ELVSS according to a voltage of the third node N3.

A first electrode of the second transistor ST2 (switching transistor) may be connected to a data line DLj, a second electrode may be connected to the first node N1, and a gate electrode may be connected to a first scan signal line GWLi. The second transistor ST2 may be turned on when a gate-on level of first scan signal is supplied to the first scan signal line GWLi to electrically connect the data line DLj and the first electrode of the first transistor ST1.

A first electrode of the third transistor ST3 (diode connection transistor) may be connected to the second node N2, a second electrode may be connected to the third node N3, and a gate electrode may be connected to a second scan signal line GCLi. The third transistor ST3 may be turned on when a gate-on level of second scan signal is supplied to the second scan signal line GCLi to electrically connect the second electrode of the first transistor ST1 and the third node N3. That is, when the third transistor ST3 is turned on, the first transistor ST1 may be diode-connected.

A first electrode of the fourth transistor ST4 (gate initialization transistor) may be connected to the third node N3, the second electrode may be connected to a first initialization power line to which a first initialization power voltage VINT is applied, and a gate electrode may be connected to a third scan signal line GILi. The fourth transistor ST4 may be turned on when a gate-on level of third scan signal is supplied to the third scan signal line GILi to supply a first initialization power voltage VINT to the third node N3.

A first electrode of the fifth transistor ST5 (first light emitting transistor) may be connected to a first power voltage line (for example, the power voltage line PL of FIG. 1) to which the first power voltage ELVDD is applied, a second electrode may be connected to the first node N1, and a gate electrode may be connected to an emission control signal line EMLi. The fifth transistor ST5 may be turned off when a gate-off level of emission control signal is supplied to the emission control signal line EMLi, and may be turned on in other cases.

A first electrode of the sixth transistor ST6 (second light emitting transistor) may be connected to the second node N2, a second electrode may be connected to a fourth node N4, and a gate electrode may be connected to the emission control signal line EMLi. The sixth transistor ST6 may be turned off when a gate-off level of emission control signal is supplied to the emission control signal line EMLi, and may be turned on in other cases.

A first electrode of the seventh transistor ST7 (light emitting initialization transistor) may be connected to a fourth node N4, a second electrode may be connected to a second initialization power line to which a second initialization power voltage AINT is applied, and a gate electrode may be connected to a fourth scan signal line GBLi. The seventh transistor ST7 may be turned on when a gate-on level of fourth scan signal is supplied to the fourth scan signal line GBLi to supply the second initialization power voltage AINT to the fourth node N4. Here, the second initialization power voltage AINT may be set to a voltage lower than the data voltage.

A first electrode of the storage capacitor Cst may be connected to the first power voltage line (for example, the power voltage line PL of FIG. 1) to which the first power voltage ELVDD is applied, and the second electrode may be connected to the third node N3. The storage capacitor Cst may store a data voltage and a voltage corresponding to a threshold voltage of the first transistor ST1.

A light emitting element LD may be connected between the fourth node N4 and the second power voltage line to which the second power voltage ELVSS is applied. The pixel PX may include at least one light emitting element LD. Here, a type of the light emitting element LD is not particularly limited. For example, the light emitting element LD may be an organic light emitting element. As another example, the light emitting element LD may be an inorganic light emitting element including a micro LED, a quantum dot, or the like. As still another example, the light emitting element LD may be a composite light emitting element including an organic material and an inorganic material.

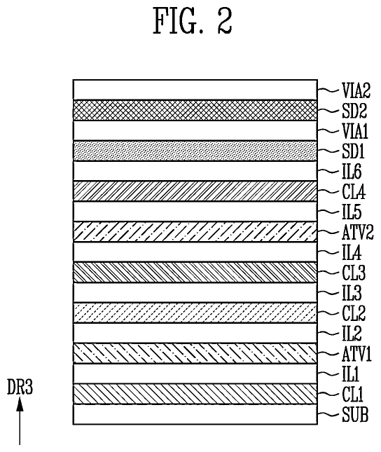

FIGS. 2 and 3 are diagrams illustrating a pixel according to an embodiment of the disclosure.

Referring to FIG. 2, the pixel PX may include a substrate SUB, a first conductive layer CL1, a first insulating layer IL1, a first active layer ATV1, a second insulating layer IL2, a second conductive layer CL2, a third insulating layer IL3, a third conductive layer CL3, a fourth insulating layer IL4, a second active layer ATV2, a fifth insulating layer IL5, a fourth conductive layer CLA, a sixth insulating layer IL6, a first SD conductive layer SD1, a first via insulating layer VIA1, a second SD conductive layer SD2, and a second via insulating layer VIA2 which are sequentially stacked.

The substrate SUB may be formed of various materials such as glass, polymer, and metal. According to a product to which the substrate SUB is applied, the substrate SUB may be rigid or flexible.

The first active layer ATV1 and the second active layer ATV2 may be a semiconductor layer. For example, the first active layer ATV1 may include a polysilicon semiconductor, and the second active layer ATV2 may include an oxide semiconductor. The first active layer ATV1 and the second active layer ATV2 may include a channel and an electrodes of a transistor.

Each of the first conductive layer CL1, the second conductive layer CL2, the third conductive layer CL3, the fourth conductive layer CL4, the first SD conductive layer SD1, and the second SD conductive layer SD2 may be a single layer or multiple layers, and may be formed using a known conductor such as gold (Au), silver (Ag), aluminum (Al), molybdenum (Mo), chromium (Cr), titanium (Ti), nickel (Ni), neodymium (Nd), copper (Cu), and platinum (Pt).

The first insulating layer IL1, the second insulating layer IL2, the third insulating layer IL3, the fourth insulating layer IL4, the fifth insulating layer IL5, and the sixth insulating layer IL6 may be interposed between adjacent conductive layers to electrically insulate the active layers ATV1 and ATV2, the first to fourth conductive layers CL1, CL2, CL3, and CL4, and the first SD conductive layer SD1. In this case, the electrode patterns may be connected to each other through a through hole formed in each of the insulating layers IL1, IL2, IL3, IL4, IL5, and IL6 as necessary. The insulating layers IL1, IL2, IL3, IL4, IL5, and IL6 may include an inorganic insulating material. For example, the insulating layers IL1, IL2, IL3, IL4, IL5, and IL6 may include silicon oxide, silicon nitride, silicon oxynitride, or the like.

The first via insulating layer VIA1 and the second via insulating layer VIA2 may be interposed between adjacent conductive layers to electrically insulate the first SD conductive layer SD1, the second SD conductive layer SD2, and a conductive layer (for example, PXE of FIG. 3) disposed on the second SD conductive layer SD2. In this case, electrode patterns may be connected to each other through a through hole formed in the via insulating layers VIA1 and VIA2 as necessary. The via insulating layers VIA1 and VIA2 may include an organic insulating material. For example, the via insulation layers VIA1 and VIA2 may include epoxy resin, phenolic resin, polyamide resin, polyimide resin, or the like.

Referring to FIG. 3, the pixel PX disposed in the display area DA may include a polysilicon semiconductor transistor TFT1, an oxide semiconductor transistor TFT2, and a light emitting element LD. The polysilicon semiconductor transistor TFT1 may correspond to any one of the transistors ST1, ST2, ST5, ST6, and ST7 described with reference to FIG. 1B, and the oxide semiconductor transistor TFT2 may correspond to any one of the transistors ST3 and ST4 described with reference to FIG. 1B.

In an embodiment, a first barrier layer BRL1 may be disposed between the first conductive layer CL1 and the substrate SUB, and a second barrier layer BRL2 may be disposed between the first conductive layer CLI and the first insulating layer IL1. The barrier layers BRL1 and BRL2 may block moisture and gas input from an outside. The barrier layers BRL1 and BRL2 may include a material equal or similar to the material of the insulating layers IL1, IL2, IL3, IL4, IL5, and IL6.

A partial pattern of the first active layer ATV1, a partial pattern of the second conductive layer CL2, a partial pattern of the third conductive layer CL3, and a partial pattern of the first SD conductive layer SD1 may configure a polysilicon semiconductor transistor TFT1. A partial pattern of the second active layer ATV2, a partial pattern of the third conductive layer CL3, a partial pattern of the fourth conductive layer CL4, and a partial pattern of the first SD conductive layer SD1 may configure an oxide semiconductor transistor TFT2. In FIG. 3, for convenience of description, only one polysilicon semiconductor transistor TFT1 and one oxide semiconductor transistor TFT2 are shown, but the pixel PX may include two or more polysilicon semiconductor transistors TFT1 and two or more oxide semiconductor transistors TFT2.

The light emitting element LD may include a pixel electrode PXE, a light emitting layer EL, and a common electrode CE.

The pixel electrode PXE may be disposed on the second via insulating layer VIA2. The pixel electrode PXE may be connected to a partial pattern of the second SD conductive layer SD2 electrically connected to the polysilicon semiconductor transistor TFT1 through a through hole.

A pixel defining layer PDL partitioning an emission area of each pixel may be disposed on the pixel electrode PXE. The pixel defining layer PDL may include an organic insulating material. For example, the pixel defining layer PDL may include a polyacrylic compound, a polyimide compound, a fluorine-based carbon compound, a benzocyclobutene compound, or the like.

The pixel defining layer PDL may expose at least a portion of an upper surface of the pixel electrode PXE and may protrude from the substrate SUB along a circumference of the pixel. The light emitting layer EL may be disposed in a pixel area surrounded by the pixel defining layer PDL.

The light emitting layer EL may include a material that may emit light. For example, the light emitting layer EL may include copper phthalocyanine, N,N-di(naphthalene-1-yl)-N,N′-diphenyl-benzidine (NPB), tris-8-hydroxyquinoline aluminum (Alq3), PEDOT, poly-phenylenevinylene-based (PPV) material, polyfluorene-based material, or the like.

The light emitting layer EL may be provided as a single layer or multiple layers including various functional layers. When the light emitting layer EL is provided as multiple layers, the light emitting layer EL may have a structure in which at least two among a hole injection layer (HIL), a hole transport layer (HTL), an emission layer, an electron transport layer (ETL), an electron injection layer (EIL), and the like are stacked.

According to an embodiment, at least a portion of the light emitting layer EL may be formed integrally across a plurality of pixel electrodes PXE, or may be formed individually to correspond to each of the plurality of pixel electrodes PXE.

The common electrode CE may be disposed on the light emitting layer EL. The common electrode CE may be disposed for each pixel, but may be disposed to cover most of the display area DA and may be shared by a plurality of pixels. The common electrode CE may include a transparent conductive material. For example, the common electrode CE may include indium tin oxide (ITO), indium zinc oxide (IZO), zinc oxide (ZnO), indium tin zinc oxide ITZO, or the like.

An encapsulation layer EN may be disposed on the common electrode CE. The encapsulation layer EN may block moisture and gas input from the outside. The encapsulation layer EN may be disposed entirely at least in the display area DA of FIG. 1A so as to entirely cover the plurality of pixels disposed in the display area DA of FIG. 1A.

The encapsulation layer EN may include at least one organic encapsulation layer and an inorganic encapsulation layer disposed on upper and lower surfaces of the organic encapsulation layer with the organic encapsulation layer interposed therebetween. For example, the encapsulation layer EN may include a first inorganic encapsulation layer EN1, a second inorganic encapsulation layer EN3, and an organic encapsulation layer EN2 interposed between the first inorganic encapsulation layer EN1 and the second inorganic encapsulation layer EN3.

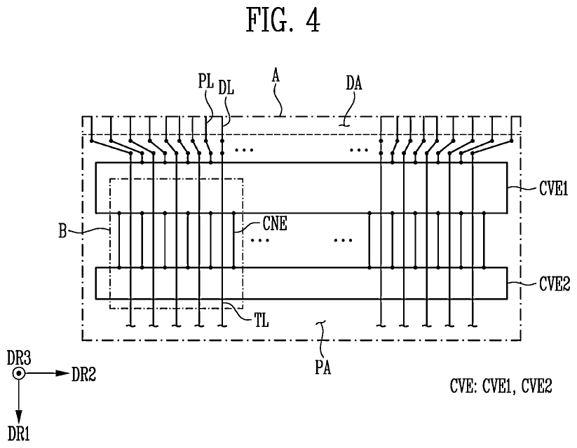

FIG. 4 is an enlarged view of an area A of FIG. 1A and is a view illustrating a constant voltage electrode according to an embodiment of the disclosure.

Referring to FIG. 4, the constant voltage electrode CVE may include a first constant voltage electrode CVE1 and a second constant voltage electrode CVE2.

The first constant voltage electrode CVE1 may be disposed to be spaced apart from the display area DA in the first direction DR1. The second constant voltage electrode CVE2 may be disposed to be spaced apart from the first constant voltage electrode CVE1 in the first direction DR1.

A connection electrode CNE may be in electrical contact with each of the first constant voltage electrode CVE1 and the second constant voltage electrode CVE2. That is, the connection electrode CNE may electrically connect the first constant voltage electrode CVE1 and the second constant voltage electrode CVE2 to each other.

The first constant voltage electrode CVE1 may be electrically connected to the power voltage line PL disposed in the display area DA. The second constant voltage electrode CVE2 may be electrically connected to a constant voltage power supply (not shown) disposed in the peripheral area PA. Accordingly, the first constant voltage electrode CVE1, the second constant voltage electrode CVE2, the connection electrode CNE, and the power voltage line PL may transmit constant voltage power provided from the constant voltage power supply to the pixel PX.

A transmission line TL extending in a first direction DR1 to traverse the first constant voltage electrode CVE1 and the second constant voltage electrode CVE2 may be disposed in the peripheral area PA. The transmission line TL may be electrically connected to an integrated circuit chip IC of FIG. 1A and/or the pad unit PD of FIG. 1A disposed in the peripheral area PA. In addition, the transmission line TL may be electrically connected to the data line DL disposed in the display area DA. Accordingly, the transmission line TL may transmit an electrical signal provided from the integrated circuit chip IC of FIG. 1A and/or the pad unit PD of FIG. 1A to the pixel PX.

A constant voltage signal (for example, the first power voltage ELVDD of FIG. 1B) may be provided to the first constant voltage electrode CVE1, the second constant voltage electrode CVE2, and the connection electrode CNE. Alternatively, a clock signal (for example, the data voltage applied to the data line DLj of FIG. 1B) may be provided to the transmission line TL. The transmission line TL may be electrically insulated from the first constant voltage electrode CVE1, the second constant voltage electrode CVE2, and the connection electrode CNE. To this end, as shown in FIG. 4, it may be designed so that the transmission line TL is disposed not to overlap the connection electrode CNE in a plan view, and a conductive layer forming the transmission line TL and a conductive layer forming the constant voltage electrode CVE are disposed in different layers with at least one insulating layer interposed therebetween. Alternatively, it may be designed so that the conductive layer forming the transmission line TL and a conductive layer forming the connection electrode CNE, the first constant voltage electrode CVE1, and the second constant voltage electrode CVE2 are disposed in different layers with at least one insulating layer interposed therebetween, and in this case, it may be designed so that the transmission line TL and the connection electrode CNE are disposed to overlap each other in a plan view as necessary.

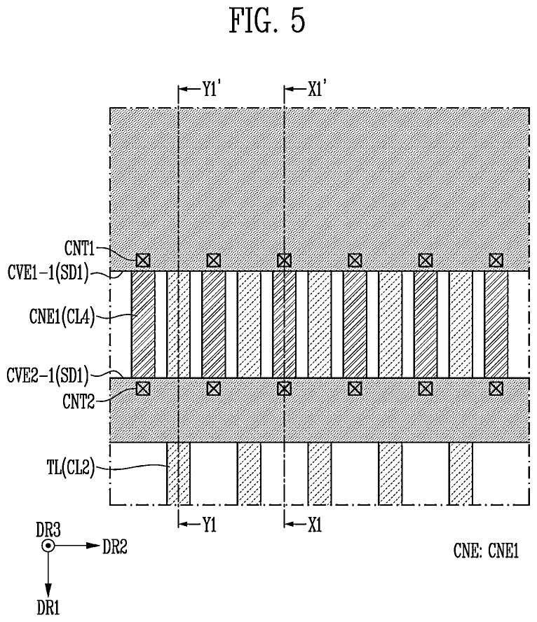

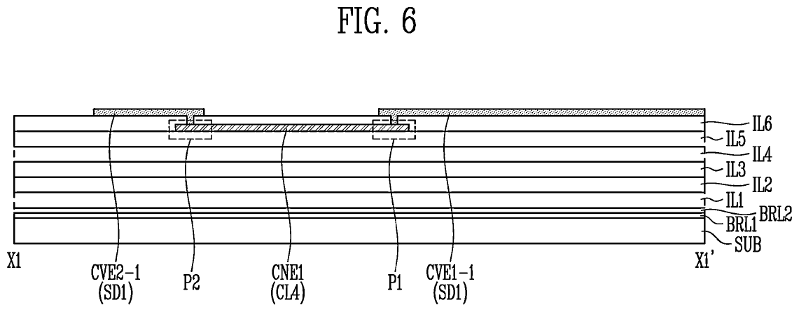

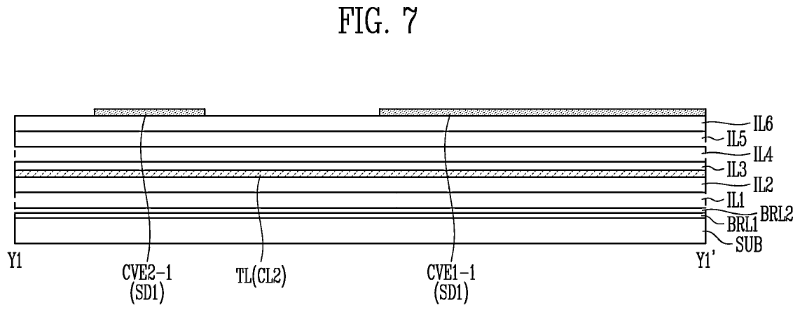

FIGS. 5 to 17 are diagrams illustrating the constant voltage electrode of FIG. 4, and FIGS. 5 to 17 show configurations of elements disposed in an area B of FIG. 4. Hereinafter, configurations included in the constant voltage electrode are described with reference to FIGS. 5 to 17. Here, in FIGS. 5, 8, 12, 14, and 16, an inorganic insulating layer is omitted.

Referring to FIGS. 5 to 7, a (2-1)-th constant voltage electrode CVE2-1 may be disposed to be spaced apart from a (1-1)-th constant voltage electrode CVE1-1 in the first direction DR1. The (1-1)-th constant voltage electrode CVE1-1 may be the first constant voltage electrode CVE1 of FIG. 4, and the (2-1)-th constant voltage electrode CVE2-1 may be the second constant voltage electrode CVE2 of FIG. 4.

The (1-1)-th constant voltage electrode CVE1-1 and the (2-1)-th constant voltage electrode CVE2-1 may be patterns included in the first SD conductive layer SD1 of FIG. 2. Here, the ‘pattern included in the first SD conductive layer SD1 of FIG. 2’ may mean that that the (1-1)-th constant voltage electrode CVE1-1, the (2-1)-th constant voltage electrode CVE2-1, and the first SD conductive layer SD1 of FIG. 2 may include a same material and be patterned at the same time using one mask.

A first connection electrode CNE1 may be in electrical contact with each of the (1-1)-th constant voltage electrode CVE1-1 and the (2-1)-th constant voltage electrode CVE2-1. More specifically, the (1-1)-th constant voltage electrode CVE1-1 may be in electrical contact with a first overlap portion Pl of the first connection electrode CNE1 through a first through hole CNT1 formed in the sixth insulating layer IL6. The first overlap portion P1 may be a portion of the first connection electrode CNE1 overlapping the (1-1)-th constant voltage electrode CVE1-1. The (2-1)-th constant voltage electrode CVE2-1 may be in electrical contact with a second overlap portion P2 of the first connection electrode CNE1 through a second through hole CNT2 formed in the sixth insulating layer IL6. The second overlap portion P2 may be a portion of the first connection electrode CNE1 overlapping the (2-1)-th constant voltage electrode CVE2-1.

The first connection electrode CNE1 may be the connection electrode CNE of FIG. 4. In addition, the first connection electrode CNE1 may be a pattern included in the fourth conductive layer CL4 of FIG. 2.

The transmission line TL may extend in the first direction DR1. The transmission line TL may overlap the (1-1)-th constant voltage electrode CVE1-1 and the (2-1)-th constant voltage electrode CVE2-1 in a plan view.

The transmission line TL may be electrically insulated from each of the (1-1)-th constant voltage electrode CVE1-1 and the (2-1)-th constant voltage electrode CVE2-1. For example, the transmission line TL may be a pattern included in the second conductive layer CL2 of FIG. 2, and thus the electrical insulation describe above may be formed by the insulating layers IL3, IL4, IL5, and IL6 interposed between the transmission line TL and the (1-1)-th constant voltage electrode CVE1-1 and the (2-1)-th constant voltage electrode CVE2-1.

The transmission line TL may be electrically insulated from the first connection electrode CNE1. For example, the transmission line TL may be a pattern included in the second conductive layer CL2 of FIG. 2, and thus the electrical insulation describe above may be formed by the insulating layer IL3, IL4, and IL5 interposed between the transmission line TL and the first connection electrode CNE1.

Meanwhile, FIGS. 5 to 7 illustrates that the first connection electrode CNE1 is a pattern included in the fourth conductive layer CLA of FIG. 2 and the transmission line TL is a pattern included in the second conductive layer CL2 of FIG. 2, but the disclosure is not limited thereto. The first connection electrode CNE1 and the transmission line TL may be formed by various conductive layers which satisfy the above-described electrical insulation. For example, the first connection electrode CNE1 may be formed by the third conductive layer CL3 of FIG. 2. As another example the first connection electrode CNE1 and the transmission line TL may be formed by the third conductive layer CL3 of FIG. 2 and the first connection electrode CNE1 and the transmission line TL do not overlap in a plan view.

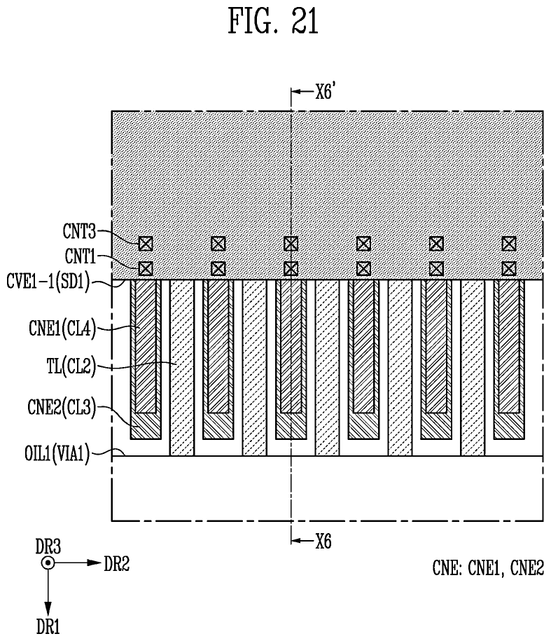

In addition, the connection electrode CNE may be a dual layer structure that includes the first connection electrode CNE1 and a second connection electrode disposed in a layer different from that of the first connection electrode CNE1 and connected to the first connection electrode CNE1. This is described later with reference to FIGS. 21 to 25.

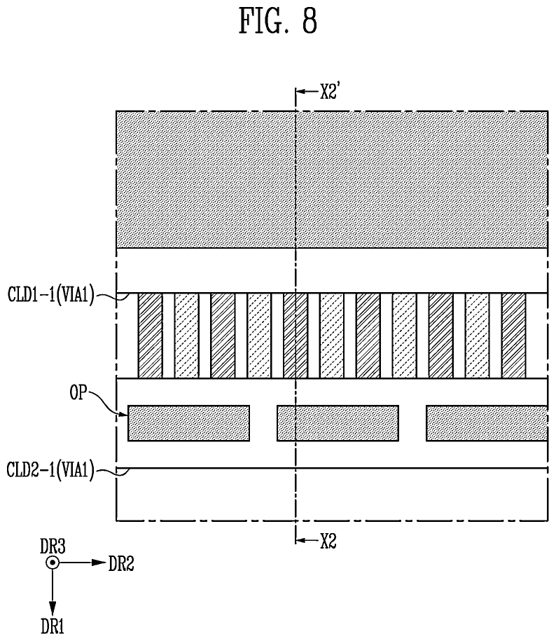

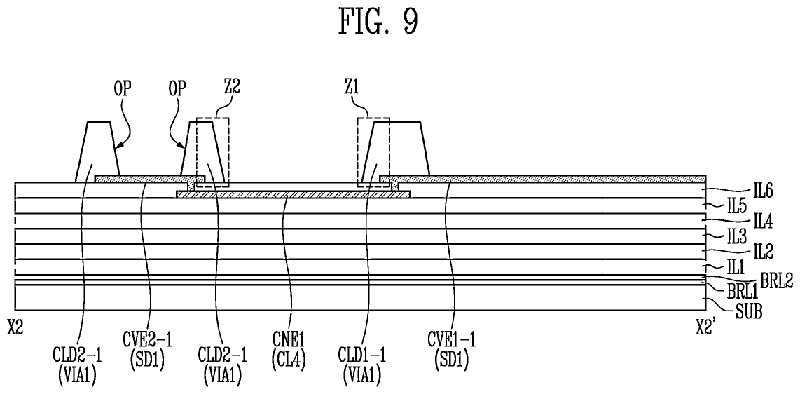

Referring to FIGS. 8 and 9, a (1-1)-th cladding layer CLD1-1 and a (2-1)-th cladding layer CLD2-1 may be disposed on the (1-1)-th constant voltage electrode CVE1-1 and the (2-1)-th constant voltage electrode CVE2-1.

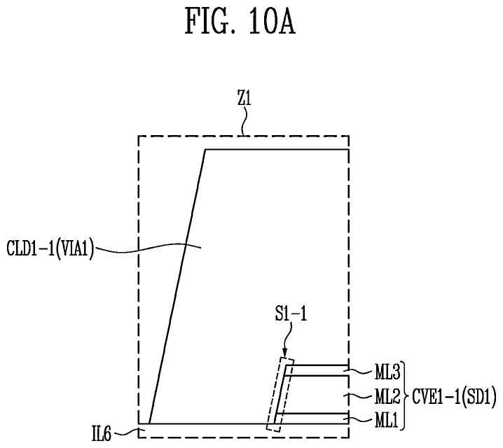

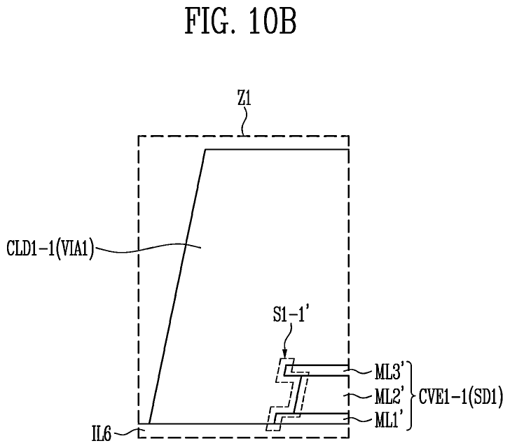

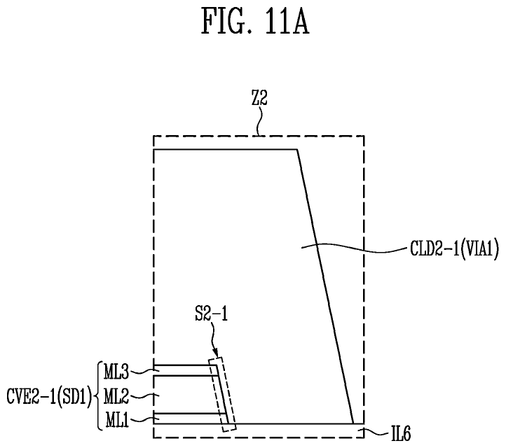

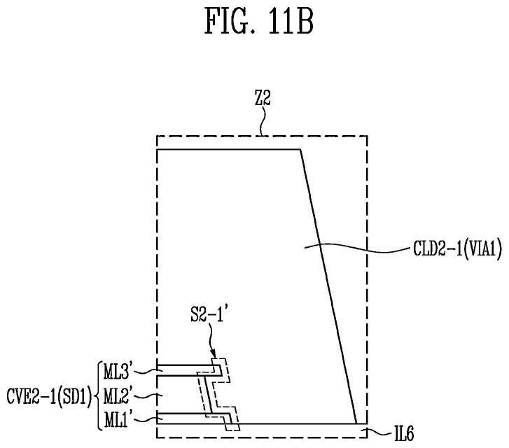

The (1-1)-th cladding layer CLD1-1 may cover at least a (1-1)-th side surface portion S1-1 of the (1-1)-th constant voltage electrode CVE1-1 facing the (2-1)-th constant voltage electrode CVE2-1 as disclosed in FIG. 10A. The (2-1)-th cladding layer CLD2-1 may cover at least a (2-1)-th side surface portion S2-1 of the (2-1)-th constant voltage electrode CVE2-1 facing the (1-1)-th constant voltage electrode CVE1-1 as disclosed in FIG. 11A. The (1-1)-th cladding layer CLD1-1 and the (2-1)-th cladding layer CLD2-1 may be a pattern included in the first via insulating layer VIA1 of FIG. 2.

In an embodiment, the (2-1)-th cladding layer CLD2-1 may entirely cover the side surface portion of the (2-1)-th constant voltage electrode CVE2-1. In this case, the (2-1)-th cladding layer CLD2-1 may include an opening OP exposing at least a portion of an upper surface of the (2-1)-th constant voltage electrode CVE2-1. Only one opening OP may be defined on the (2-1)-th constant voltage electrode CVE2-1, or a plurality of openings OP may be defined as shown in FIG. 8.

Referring to FIG. 10A, the (1-1)-th constant voltage electrode CVE1-1 may have a stack structure of a first metal layer ML1, a second metal layer ML2, and a third metal layer ML3. The second metal layer ML2 may include a material having a relatively low electrical resistance compared to the first and third metal layers ML1 and ML3. For example, the second metal layer ML2 may include aluminum, and the first and third metal layers ML1 and ML3 may include titanium. Here, the first to third metal layers ML1, ML2, and ML3 forming the (1-1)-th side surface portion S1-1 of the (1-1)-th constant voltage electrode CVE1-1 may be covered by the (1-1)-th cladding layer CLD1-1.

Referring to FIG. 10B, in another embodiment, a side surface of a second metal layer ML2′ may be recessed from side surface of a first metal layer ML1′ and a side surface of a third metal layer ML3′. Accordingly, an undercut structure as shown in

FIG. 10B may be formed. This may be a structure formed by a difference of an etching rate of a material included in the second metal layer ML2′ and a material included in the first metal layer ML1′ and the third metal layer ML3′ in a formation process of the (1-1)-th constant voltage electrode CVE1-1. Also in this case, the first to third metal layers ML1′, ML2′, and ML3′ forming a (1-1)-th side surface portion S1-1′ of the (1-1)-th constant voltage electrode CVE1-1 may be covered by the (1-1)-th cladding layer CLD1-1.

Referring to FIG. 11A, the (2-1)-th constant voltage electrode CVE2-1 may also have a stack structure of a first metal layer ML1, a second metal layer ML2, and a third metal layer ML3. Here, the first to third metal layers ML1, ML2, ML3 forming the (2-1)-th side surface portion S2-1 of the (2-1)-th constant voltage electrode CVE2-1 may be covered by the (2-1)-th cladding layer CLD2-1.

Referring to FIG. 11B, in another embodiment, the side surface of the second metal layer ML2′ may be recessed from the side surface of the first metal layer ML1′ and the side surface of the third metal layer ML3′. Accordingly, an undercut structure as shown in FIG. 11B may be formed. This may be a structure formed by a difference of an etching rate of the material included in the second metal layer ML2′ and the material included in the first metal layer ML1′ and the third metal layer ML3′ in a formation process of the (2-1)-th constant voltage electrode CVE2-1. Also in this case, the first to third metal layers ML1′, ML2′, and ML3′ configuring a (2-1)-th side surface portion S2-1′ of the (2-1)-th constant voltage electrode CVE2-1 may be covered by the (2-1)-th cladding layer CLD2-1.

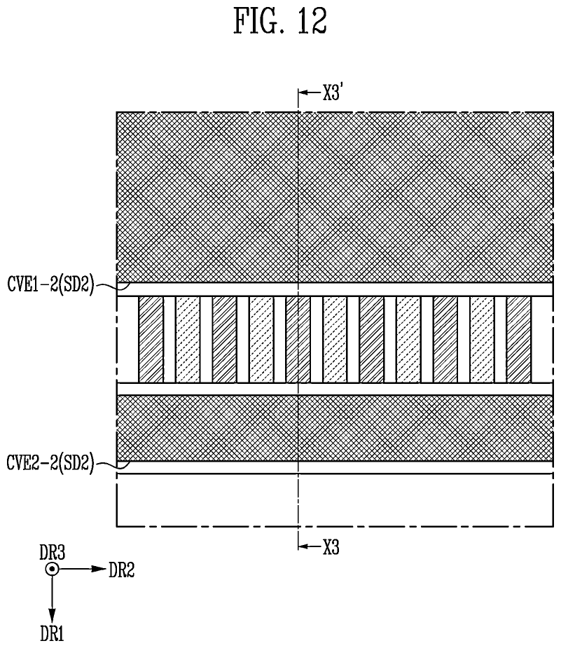

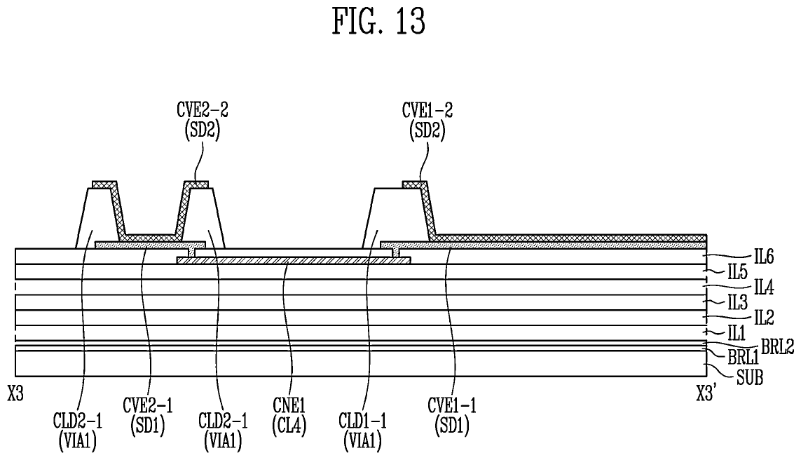

Referring to FIGS. 12 and 13, a (1-2)-th constant voltage electrode CVE1-2 and a (2-2)-th constant voltage electrode CVE2-2 may be disposed on the (1-1)-th cladding layer CLD1-1 and the (2-1)-th cladding layer CLD2-1. The (2-2)-th constant voltage electrode CVE2-2 may be disposed to be spaced apart from the (2-1)-th constant voltage electrode CVE2-1 in the first direction DR1. The (1-2)-th constant voltage electrode CVE1-2 may be the first constant voltage electrode CVE1 of FIG. 4, and the (2-2)-th constant voltage electrode CVE2-2 may be the second constant voltage electrode CVE2 of FIG. 4. The (1-2)-th constant voltage electrode CVE1-2 and the (2-2)-th constant voltage electrode CVE2-2 may be a pattern included in the second SD conductive layer SD2 of FIG. 2.

The (1-2)-th constant voltage electrode CVE1-2 may extend from an upper surface of the (1-1)-th cladding layer CLD1-1 in a direction opposite to the first direction DR1, and may be in direct contact with at least a portion of an upper surface of the (1-1)-th constant voltage electrode CVE1-1.

The (2-2)-th constant voltage electrode CVE2-2 may extend from an upper surface of the (2-1)-th cladding layer CLD2-1 in the first direction DR1, and may be in direct contact with at least a portion of the upper surface of the (2-1)-th constant voltage electrode CVE2-1.

In an embodiment, when the (2-1)-th cladding layer CLD2-1 entirely covers the side surface portion of the (2-1)-th constant voltage electrode CVE2-1 and includes the opening OP of FIG. 9 exposing at least a portion of the upper surface of the (2-1)-th constant voltage electrode CVE2-1, the (2-2)-th constant voltage electrode CVE2-2 may directly contact the upper surface of the (2-1)-th constant voltage electrode CVE2-1 exposed by the opening OP of FIG. 9.

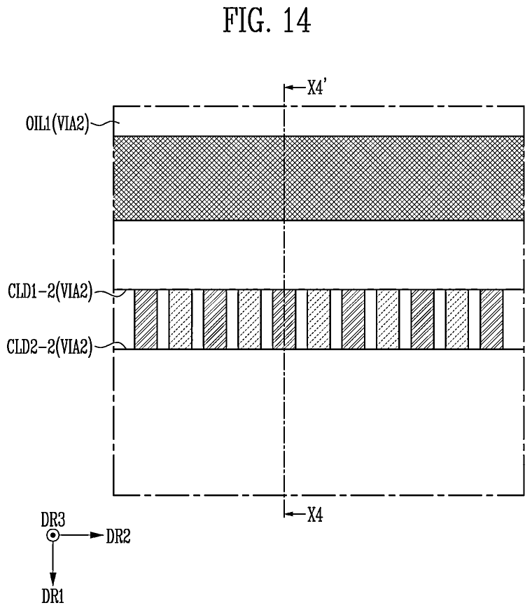

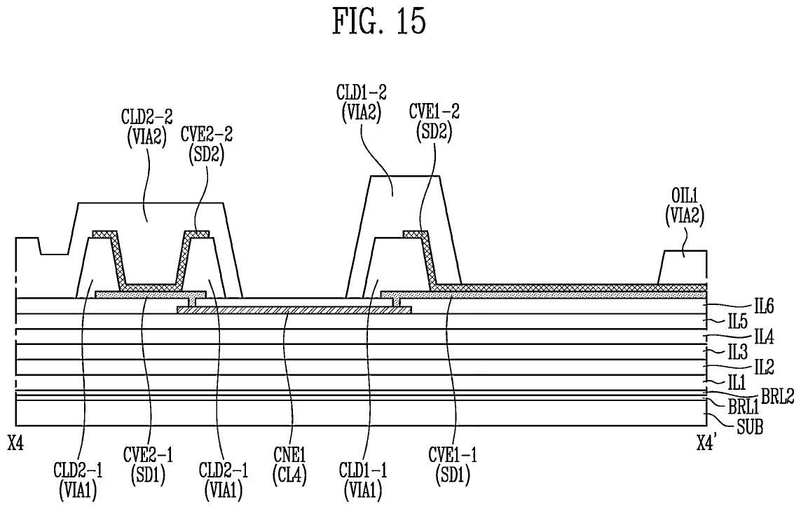

Referring to FIGS. 14 and 15, a first organic layer OIL1, a (1-2)-th cladding layer CLD1-2, and a (2-2)-th cladding layer CLD2-2 may be disposed on the (1-2)-th constant voltage electrode CVE1-2 and the (2-2)-th constant voltage electrode CVE2-2. The first organic layer OIL1, the (1-2)-th cladding layer CLD1-2, and the (2-2)-th cladding layer CLD2-2 may be a pattern included in the second via insulating layer VIA2 of FIG. 2.

The first organic layer OIL1 may be disposed on the (1-2)-th constant voltage electrode CVE1-2 on the (1-1)-th constant voltage electrode CVE1-1. According to an embodiment, at least a portion of the (1-2)-th constant voltage electrode CVE1-2 may be interposed between the first organic layer OIL1 and the (1-1)-th constant voltage electrode CVE1-1.

The (1-2)-th cladding layer CLD1-2 may be disposed to be spaced apart from the first organic layer OIL1 in the first direction DR1. The (1-2)-th cladding layer CLD1-2 may cover the (1-2)-th side surface portion disposed on the (1-1)-th cladding layer CLD1-1 among side surface portions of the (1-2)-th constant voltage electrode CVE1-2.

The (2-2)-th cladding layer CLD2-2 may be disposed to be spaced apart from the (1-2)-th cladding layer CLD1-2 in the first direction DR1. The (2-2)-th cladding layer CLD2-2 may entirely cover the (2-2)-th constant voltage electrode CVE2-2.

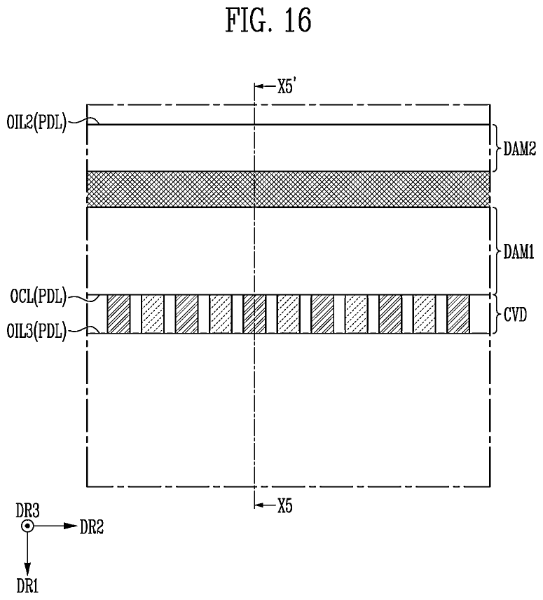

Referring to FIGS. 16 and 17, an organic cover layer OCL, a second organic layer OIL2, and a third organic layer OIL3 may be disposed on the first organic layer OIL1, the (1-2)-th cladding layer CLD1-2, and the (2-2)-th cladding layer CLD2-2. The organic cover layer OCL, the second organic layer OIL2, and the third organic layer OIL3 may be a pattern included in the pixel defining layer PDL of FIG. 3.

The second organic layer OIL2 may extend from an upper surface of the first organic layer OIL1 in the first direction DR1 and may be disposed on a portion of the upper surface of the (1-1)-th constant voltage electrode CVE1-1. According to an embodiment, at least a portion of the (1-2)-th constant voltage electrode CVE1-2 may be interposed between the second organic layer OIL2 and the (1-1)-th constant voltage electrode CVE1-1.

A first spacer pattern SPC1 may be disposed on the second organic layer OIL2. The first spacer pattern SPC1 may include an organic insulating material and/or an inorganic insulating material.

A portion of the first organic layer OIL1, the second organic layer OIL2, and the first spacer pattern SPC1 may form the second dam structure DAM2 described with reference to FIG. 1A. The second dam structure DAM2 may serve to block the organic encapsulation layer EN2.

The organic cover layer OCL may be disposed to be spaced apart from the second organic layer OIL2 in the first direction DR1. The organic cover layer OCL may cover at least a portion of the (1-2)-th cladding layer CLD1-2. According to embodiments, the organic cover layer OCL may entirely cover the (1-2)-th cladding layer CLD1-2.

The (1-1)-th cladding layer CLD1-1, the (1-2)-th cladding layer CLD1-2, and the organic cover layer OCL may form the first dam structure DAM1 described with reference to FIG. 1A. The first dam structure DAM1 may be disposed to block the organic encapsulation layer EN2 that is not blocked by the second dam structure DMA2.

The third organic layer OIL3 may be disposed to be spaced apart from the organic cover layer OCL in the first direction DR1. The third organic layer OIL3 may entirely cover the (2-2)-th cladding layer CLD2-2.

A second spacer pattern SPC2 may be disposed on the third organic layer OIL3. The second spacer pattern SPC2 may include substantially the same material as the first spacer pattern SPC1.

As described above, the organic encapsulation layer EN2 may be blocked by the second dam structure DAM2. In this case, the first inorganic encapsulation layer EN1 and the second inorganic encapsulation layer EN3 may contact each other on an upper surface of the second dam structure DMA2. In addition, the first inorganic encapsulation layer EN1 and the second inorganic encapsulation layer EN3 may also be disposed on the third organic layer OIL3 by extending in the direction opposite to the first direction DR1 from an upper surface of the second dam structure DAM2 in a state in which the first inorganic encapsulation layer EN1 and the second inorganic encapsulation layer EN3 are in contact with each other.

Here, in an area between the (1-1)-th constant voltage electrode CVE1-1 and the (2-1)-th constant voltage electrode CVE2-1, the first inorganic encapsulation layer EN1 and the second inorganic encapsulation layer EN3 may be in contact with each other. A CVD area CVD in which an organic insulating material is not interposed between the connection electrode CNE and the first inorganic encapsulation layer EN1 may be defined.

Referring to FIGS. 10A and 17 again, the (1-1)-th side surface portion S1-1 of the (1-1)-th constant voltage electrode CVE1-1 may be covered by the (1-1)-th cladding layer CLD1-1. The (1-1)-th cladding layer CLD1-1 may protect the (1-1)-th side surface portion S1-1 of the (1-1)-th constant voltage electrode CVE1-1 when forming the (1-2)-th constant voltage electrode CVE1-2. Accordingly, the (1-1)-th side surface portion S1-1, which is relatively vulnerable to damage, may not be substantially damaged when forming the (1-2)-th constant voltage electrode CVE1-2, and thus reliability of the first constant voltage electrode CVE1 including the (1-1)-th constant voltage electrode CVE1-1 may be improved.

Referring to FIGS. 10B and 17 again, even in a case where the undercut structure as shown of FIG. 10B is formed, the (1-1)-th side surface portion S1-1′ of the (1-1)-th constant voltage electrode CVE1-1 may be covered by the (1-1)-th cladding layer CLD1-1. Here, as the above-described undercut structure is covered by the (1-1)-th cladding layer CLD1-1, reliability of other elements disposed on the (1-1)-th cladding layer CLD1-1 covering the (1-1)-th side surface portion S1-1′ of the (1-1)-th constant voltage electrode CVE1-1 may be sufficiently secured. That is, a problem such as disconnection of the other elements due to the above-described undercut structure may not substantially occur.

Referring to FIGS. 11A and 17 again, the (2-1)-th side surface portion S2-1 and another side surface portion of the (2-1)-th constant voltage electrode CVE2-1 may be covered by the (2-1)-th cladding layer CLD2-1. The (2-1)-th cladding layer CLD2-1 may serve to entirely protect a side surface portion including the (2-1)-th side surface portion S2-1 of the (2-1)-th constant voltage electrode CVE2-1 when forming the (2-2)-th constant voltage electrode CVE2-2. Accordingly, a side surface portion of the (2-1)-th constant voltage electrode CVE2-1, which is relatively vulnerable to damage, may not be substantially damaged when forming the (2-2)-th constant voltage electrode CVE2-2, and thus reliability of the second constant voltage electrode CVE2 including the (2-1)-th constant voltage electrode CVE2-1 may be improved.

Referring to FIGS. 11B and 17 again, even in a case where the undercut structure as shown of FIG. 11B is formed, the (2-1)-th side surface portion S2-1′ of the (2-1)-th constant voltage electrode CVE2-1 may be covered by the (2-1)-th cladding layer CLD2-1. Here, as the above-described undercut structure is covered by the (2-1)-th cladding layer CLD2-1, reliability of other elements disposed on the (2-1)-th cladding layer CLD2-1 covering the (2-1)-th side surface portion S2-1′ of the (2-1)-th constant voltage electrode CVE2-1 may be sufficiently secured.

Referring to FIGS. 15 and 17 again, the (1-2)-th side surface portion disposed on the (1-1)-th cladding layer CLD1-1 among the side surface portions of the (1-2)-th constant voltage electrode CVE1-2 may be covered by the (1-2)-th cladding layer CLD1-2. Accordingly, reliability of other elements disposed on the (1-2)-th cladding layer CLD1-2 covering the (1-2)-th side surface portion of the (1-2)-th constant voltage electrode CVE1-2 may be sufficiently secured. For example, even in a case where the (1-2)-th constant voltage electrode CVE1-2 has the stack structure of the first to third metal layers ML1′, ML2′, and ML3′ described with reference to FIG. 10B and the (1-2)-th side surface portion has the undercut structure described with reference to FIG. 10B, sufficient reliability may be secured.

Referring to FIGS. 15 and 17 again, a side surface portion of the (2-2)-th constant voltage electrode CVE2-2 may be covered by the (2-2)-th cladding layer CLD2-2. Accordingly, reliability of other elements disposed on the (2-2)-th cladding layer CLD2-2 covering the side surface portion of the (2-2)-th constant voltage electrode CVE2-2 may be sufficiently secured. For example, even in a case where the (2-2)-th constant voltage electrode CVE2-2 has the stack structure of the first to third metal layers ML1′, ML2′, and ML3′ described with reference to FIG. 11B and the side surface portion of the (2-2)-th constant voltage electrode CVE2-2 has the undercut structure described with reference to FIG. 11B, sufficient reliability may be secured.

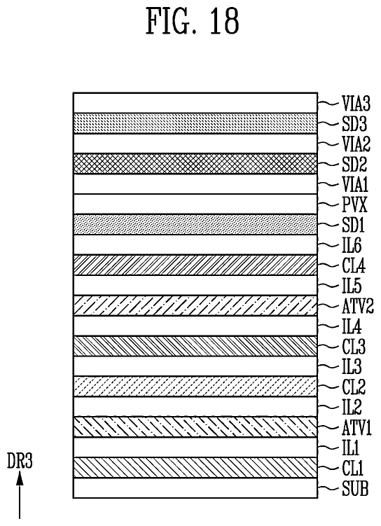

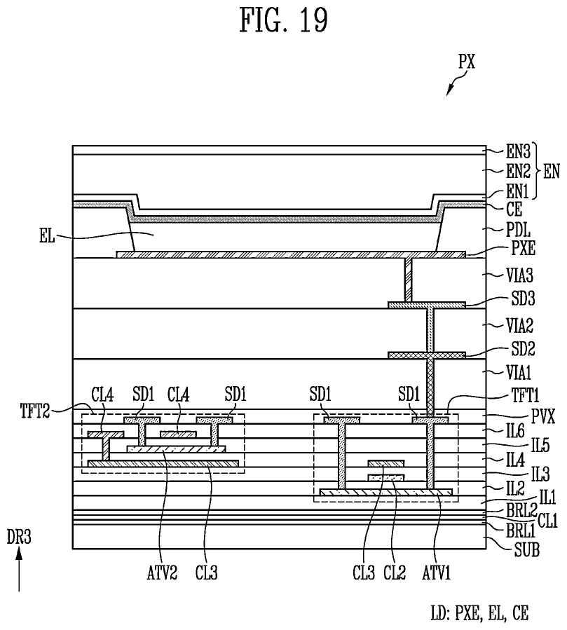

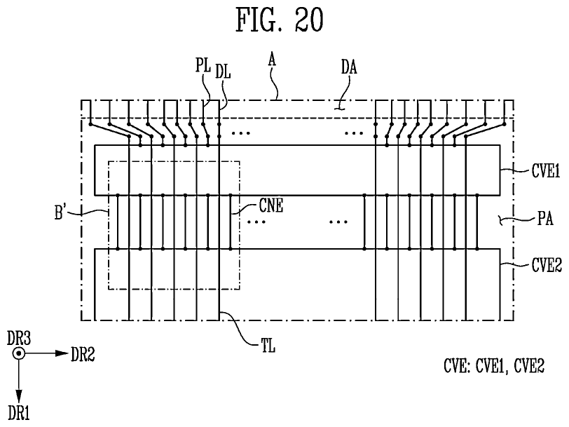

FIGS. 18 and 19 are diagrams illustrating a structure of a pixel according to another embodiment of the disclosure.

Referring to FIG. 18, the pixel PX may include a substrate SUB, a first conductive layer CL1, a first insulating layer IL1, a first active layer ATV1, a second insulating layer IL2, a second conductive layer CL2, a third insulating layer IL3, a third conductive layer CL3, a fourth insulating layer IL4, a second active layer ATV2, a fifth insulating layer IL5, a fourth conductive layer CL4, a sixth insulating layer IL6, a first SD conductive layer SD1, a passivation layer PVX, a first via insulating layer VIA1, a second SD conductive layer SD2, a second via insulating layer VIA2, a third SD conductive layer SD3, and a third via insulating layer VIA3 which are sequentially stacked.

Hereinafter, a description of a content that overlaps the content described with reference to FIG. 2 is omitted.

The third conductive layer SD3 may be a single layer or multiple layers, and may be formed using a known conductor such as gold (Au), silver (Ag), aluminum (Al), molybdenum (Mo), chromium (Cr), titanium (Ti), nickel (Ni), neodymium (Nd), copper (Cu), and platinum (Pt).

The passivation layer PVX may include an inorganic insulating material. For example, the passivation layer PVX may include silicon oxide, silicon nitride, silicon oxynitride, or the like.

The third via insulating layer VIA3 may include an organic insulating material. For example, the third via insulating layer VIA3 may include epoxy resin, phenolic resin, polyamide resin, polyimide resin, or the like.

Referring to FIG. 19, the pixel PX disposed in the display area DA may include a polysilicon semiconductor transistor TFT1, an oxide semiconductor transistor TFT2, and a light emitting element LD.

Hereinafter, a description of a content that overlaps the content described with reference to FIG. 3 is omitted.

The pixel electrode PXE may be disposed on the third via insulating layer VIA3. The pixel electrode PXE may be connected to a partial pattern of the third SD conductive layer SD3 electrically connected to the polysilicon semiconductor transistor TFT1 through a through hole. In this case, the partial pattern of the third SD conductive layer SD3 may be connected to a partial pattern of the second SD conductive layer SD2 electrically connected to the polysilicon semiconductor transistor TFT1 through a through hole.

FIG. 20 is an enlarged view of an area A of FIG. 1A which illustrates a constant voltage electrode according to another embodiment of the disclosure.

Referring to FIG. 20, the constant voltage electrode CVE may include a first constant voltage electrode CVE1 and a second constant voltage electrode CVE2. The first constant voltage electrode CVE1 and the second constant voltage electrode CVE2 may be electrically connected through the connection electrode CNE. A transmission line TL may be disposed in the peripheral area PA. Here, the configurations CVE1, CVE2, CNE, and TL, an electrical connection relationship between the configurations CVE1, CVE2, CNE, and TL and other elements (for example, PL, DL, and the like), and the like may be substantially equal (or similar) to the content described with reference to FIG. 4. Therefore, an overlapping description is omitted.

FIGS. 21 to 35 are diagrams illustrating the constant voltage electrode of FIG. 20, and FIGS. 21 to 35 show configurations of elements disposed in an area B′ of FIG. 20. Hereinafter, configurations included in the constant voltage electrode are described with reference to FIGS. 21 to 35. Here, in FIGS. 21, 24, 26, 30, 32, and 34, an inorganic insulating layer is omitted.

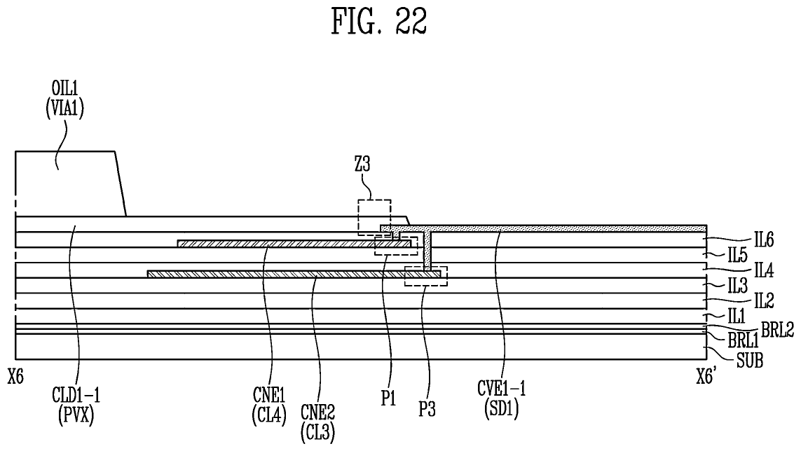

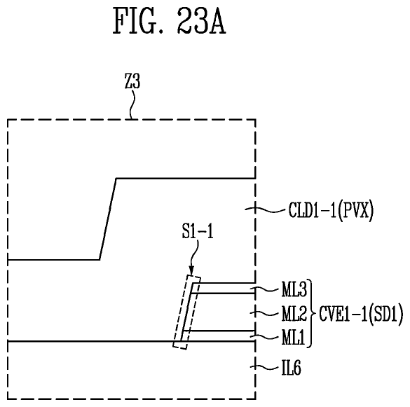

Referring to FIGS. 21 and 22, a (1-1)-th constant voltage electrode CVE1-1, a first connection electrode CNE1, a second connection electrode CNE2, a transmission line TL, and a first organic layer OIL1 may be disposed.

The (1-1)-th constant voltage electrode CVE1-1 may be the first constant voltage electrode CVE1 of FIG. 20. The (1-1)-th constant voltage electrode CVE1-1 may be a pattern included in the first SD conductive layer SD1 of FIG. 18.

A first connection electrode CNE1 may be in electrical contact with the (1-1)-th constant voltage electrode CVE1-1. More specifically, the (1-1)-th constant voltage electrode CVE1-1 may be in electrical contact with a first overlap portion P1 of the first connection electrode CNE1 through a first through hole CNT1 formed in the sixth insulating layer IL6. The first overlap portion P1 may be a portion of the first connection electrode CNE1 overlapping the (1-1)-th constant voltage electrode CVE1-1. The first connection electrode CNE1 may be a pattern included in the fourth conductive layer CL4 of FIG. 18.

A second connection electrode CNE2 may be in electrical contact with the (1-1)-th constant voltage electrode CVE1-1. More specifically, the (1-1)-th constant voltage electrode CVE1-1 may be in electrical contact with a third overlap portion P3 of the second connection electrode CNE2 through a third through hole CNT3 formed in the insulating layers IL4, IL5, and IL6. The third overlap portion P3 may be a portion of the second connection electrode CNE2 that overlaps the (1-1)-th constant voltage electrode CVE1-1 and does not overlap the first connection electrode CNE1. The second connection electrode CNE2 may be a pattern included in the third conductive layer CL3 of FIG. 18.

The first connection electrode CNE1 and the second connection electrode CNE2 may constitute the connection electrode CNE of FIG. 20. As described above, the connection electrode CNE may include two or more conductive layers disposed in different layers. In this case, an electrical resistance of the connection electrode CNE may be relatively low, and thus driving efficiency may be improved.

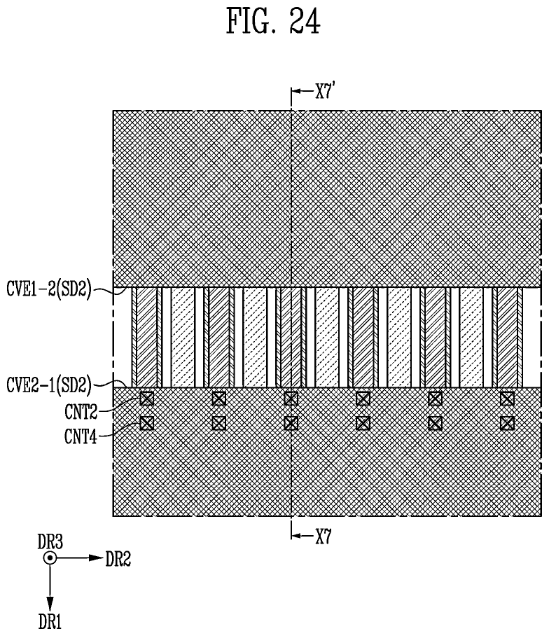

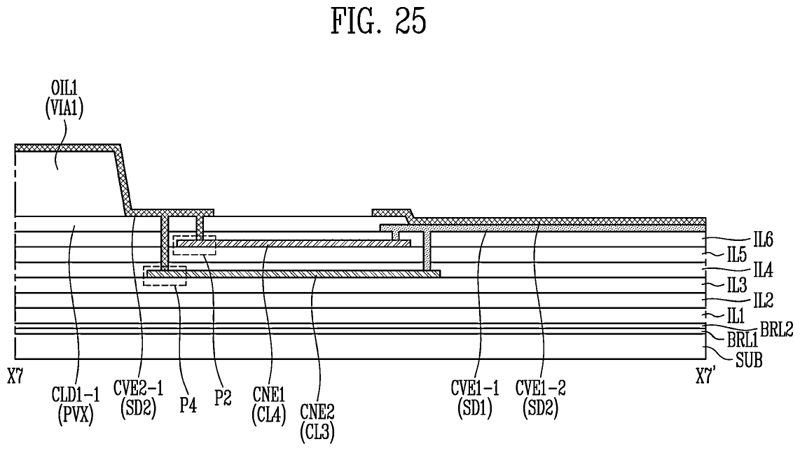

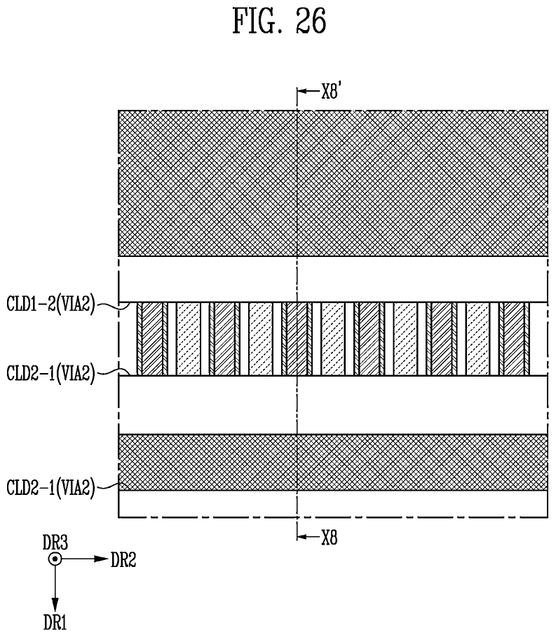

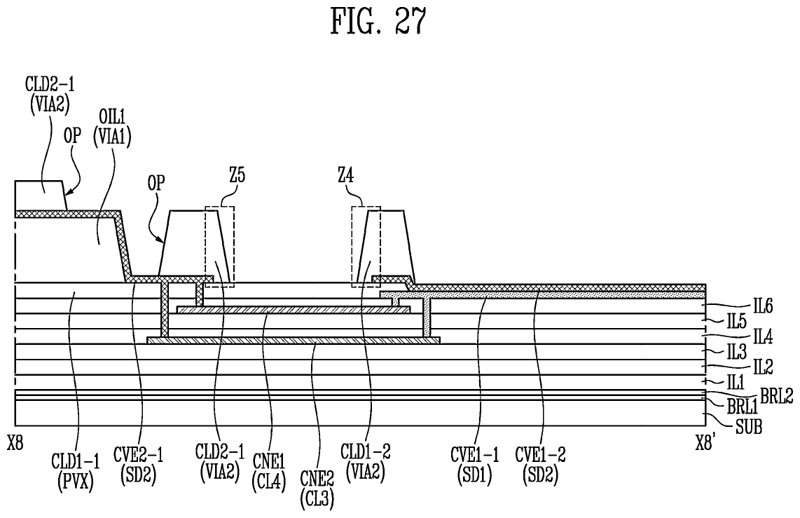

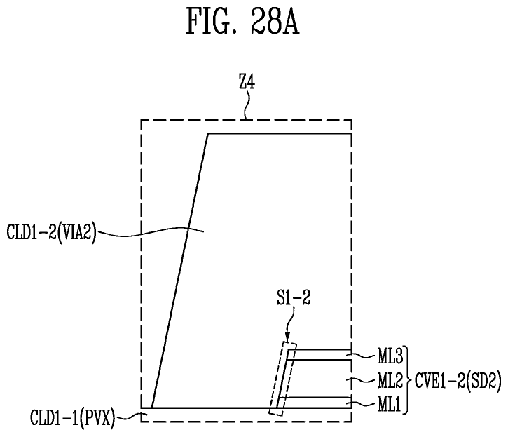

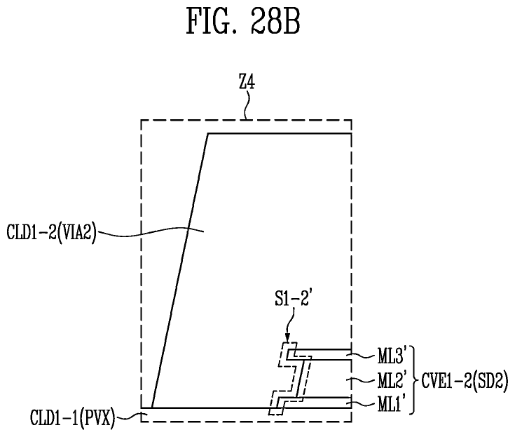

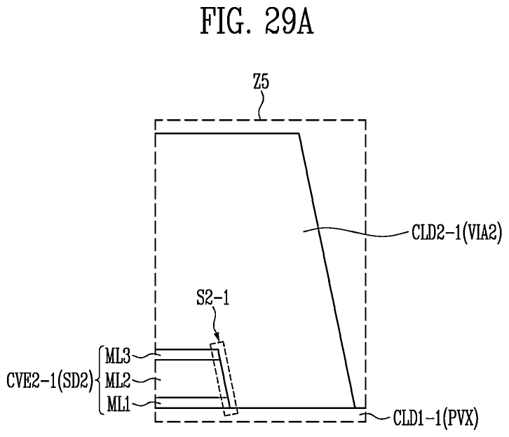

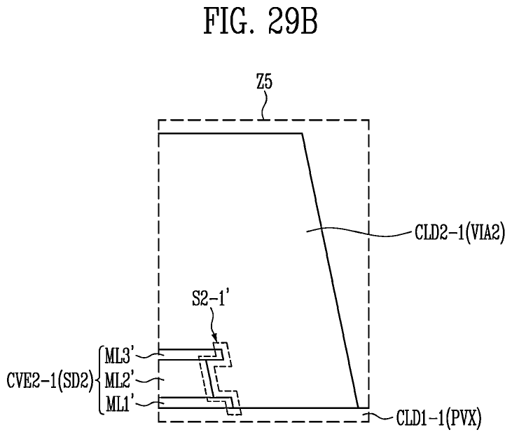

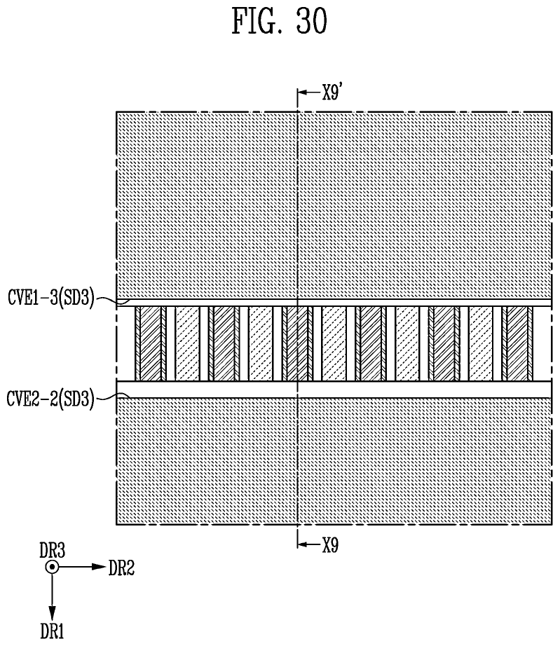

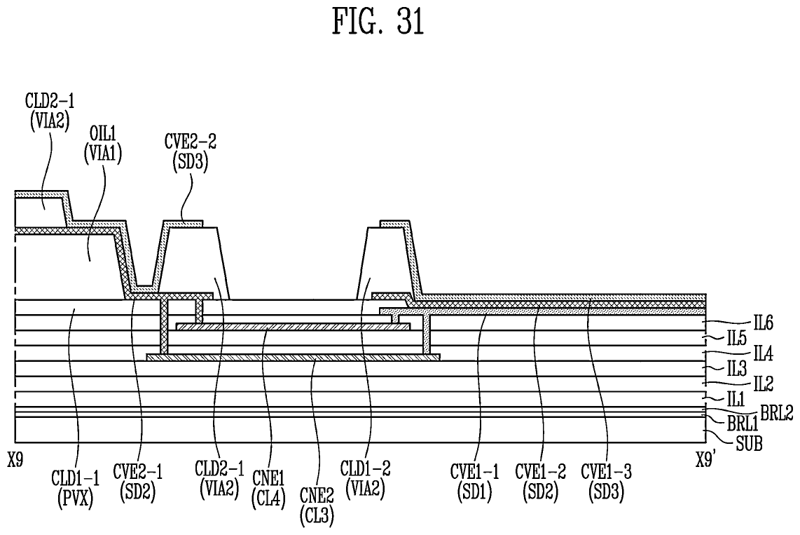

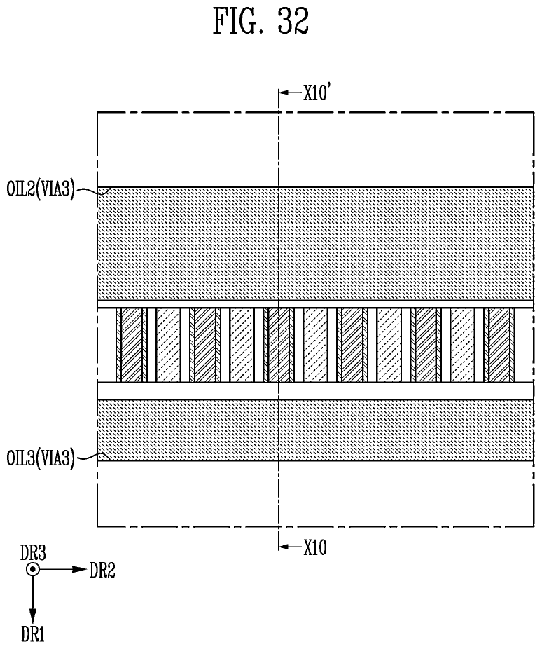

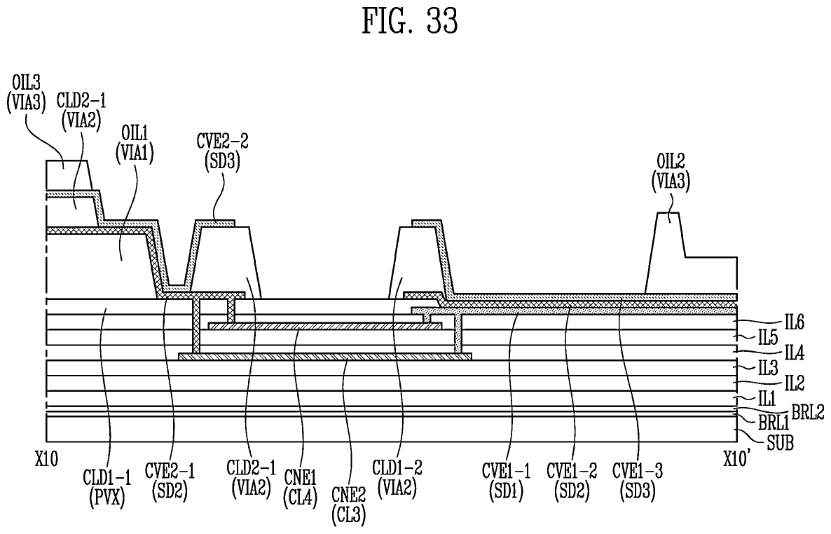

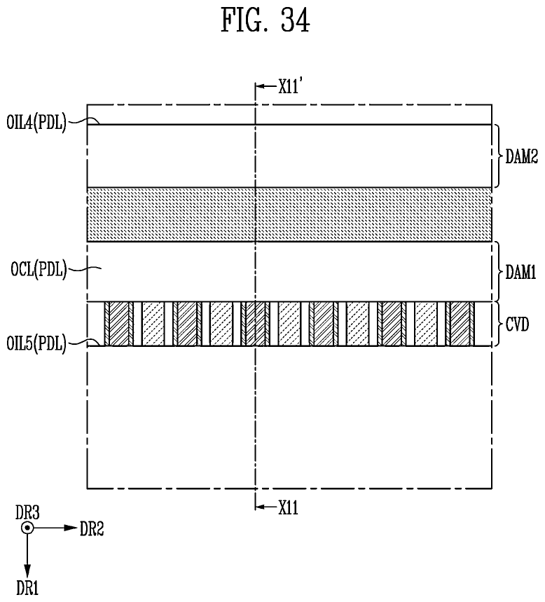

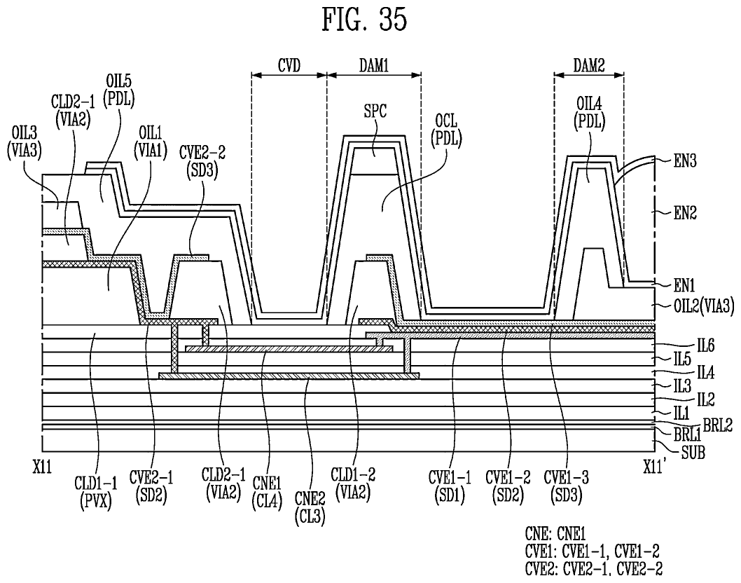

The transmission line TL may extend in the first direction DR1. The transmission line TL may overlap a (1-1)-th constant voltage electrode CVE1-1 and a (2-1)-th constant voltage electrode CVE2-1 of FIG. 24 to be described later in a plan view. In this case, the transmission line TL may be electrically insulated from each of the (1-1)-th constant voltage electrode CVE1-1 and the (2-1)-th constant voltage electrode CVE2-1 of FIG. 24. In addition, the transmission line TL may be electrically insulated from connection electrodes CNE1 and CNE2. Meanwhile, in FIG. 21, the transmission line TL is shown as a pattern included in the second conductive layer CL2 of FIG. 18, but the disclosure is not limited thereto. The transmission line TL may be formed by various conductive layers that satisfies the above-described electrical insulation.

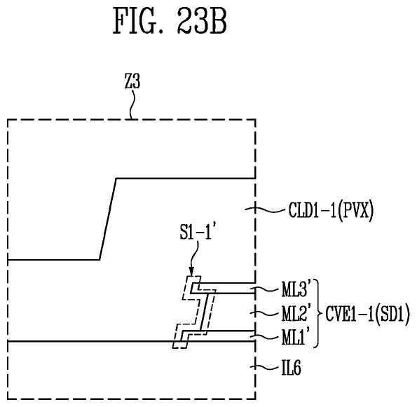

The (1-1)-th cladding layer CLD1-1 may cover a (1-1)-th side surface portion S1-1 of the (1-1)-th constant voltage electrode CVE1-1 (see FIGS. 23A and 24) which faces a (2-1)-th constant voltage electrode CVE2-1. The (1-1)-th cladding layer CLD1-1 may be a pattern included in the passivation layer PVX of FIG. 18.

The first organic layer OIL1 may be disposed on the (1-1)-th cladding layer CLD1-1. The first organic layer OIL1 may be a pattern included in the first via insulating layer VIA1 of FIG. 18.

Referring to FIG. 23A, the (1-1)-th constant voltage electrode CVE1-1 may have a stack structure of a first metal layer ML1, a second metal layer ML2, and a third metal layer ML3. The second metal layer ML2 may include a material having a relatively low electrical resistance compared to the first and third metal layers ML1 and ML3. For example, the second metal layer ML2 may include aluminum, and the first and third metal layers ML1 and ML3 may include titanium. Here, the first to third metal layers ML1, ML2, and ML3 forming the (1-1)-th side surface portion S1-1 of the (1-1)-th constant voltage electrode CVE1-1 may be covered by the (1-1)-th cladding layer CLD1-1.

Referring to FIG. 23B, in another embodiment, a side surface of a second metal layer ML2′ may be recessed from a side surface of a first metal layer ML1′ and a side surface of a third metal layer ML3′. Accordingly, an undercut structure as shown in FIG. 23B may be formed. This may be a structure formed by a difference of an etching rate of a material included in the second metal layer ML2′ and a material included in the first metal layer ML1′ and the third metal layer ML3′ in a formation process of the (1-1)-th constant voltage electrode CVE1-1. Also in this case, the first to third metal layers ML1′, ML2′, and ML3′ configuring a (1-1)-th side surface portion S1-1′ of the (1-1)-th constant voltage electrode CVE1-1 may be covered by the (1-1)-th cladding layer CLD1-1.

Referring to FIGS. 24 and 25, a (1-2)-th constant voltage electrode CVE1-2 and a (2-1)-th constant voltage electrode CVE2-1 may be disposed on the passivation layer PVX. The (2-1)-th constant voltage electrode CVE2-1 may be disposed to be spaced apart from the (1-2)-th constant voltage electrode CVE1-2 in the first direction DR1. The (1-2)-th constant voltage electrode CVE1-2 may be included in the first constant voltage electrode CVE1 of FIG. 20, and the (2-1)-th constant voltage electrode CVE2-1 may be included in the second constant voltage electrode CVE2 of FIG. 20. The (1-2)-th constant voltage electrode CVE1-2 and the (2-1)-th constant voltage electrode CVE2-1 may be a pattern included in the second SD conductive layer SD2 of FIG. 18.

The (1-2)-th constant voltage electrode CVE1-2 may extend from an upper surface of the (1-1)-th cladding layer CLD1-1 in the direction opposite to the first direction DR1, and may be in direct contact with at least a portion of an upper surface of the (1-1)-th constant voltage electrode CVE1-1.

The (2-1)-th constant voltage electrode CVE2-1 may extend from an upper surface of the first organic layer OIL1 in the direction opposite to the first direction DR1 and may be disposed on the (1-1)-th cladding layer CLD1-1.

The (2-1)-th constant voltage electrode CVE2-1 may be in electrical contact with each of the first connection electrode CNE1 and the second connection electrode CNE2. More specifically, the (2-1)-th constant voltage electrode CVE2-1 may be in electrical contact with a second overlap portion P2 of the first connection electrode CNE1 through a second through hole CNT2 formed in the sixth insulating layer IL6 and the passivation layer PVX. The second overlap portion P2 may be a portion of the first connection electrode CNE1 overlapping the (2-1)-th constant voltage electrode CVE2-1. In addition, the (2-1)-th constant voltage electrode CVE2-1 may be in electrical contact with a fourth overlap portion P4 of the second connection electrode CNE2 through a fourth through hole CNT4 formed in the insulating layers IL4, IL5, and IL6 and the passivation layer PVX. The fourth overlap portion P4 may be a portion of the second connection electrode CNE2 that overlaps the (2-1)-th constant voltage electrode CVE2-1 and does not overlap the first connection electrode CNE1.

Referring to FIGS. 26 and 27, a (1-2)-th cladding layer CLD1-2 and a (2-1)-th cladding layer CLD2-1 may be disposed on the (2-1)-th constant voltage electrode CVE2-1 and the (2-1)-th constant voltage electrode CVE2-1.

The (1-2)-th cladding layer CLD1-2 may cover at least a (1-2)-th side surface portion S1-2 of the (1-2)-th constant voltage electrode CVE1-2 (see FIG. 28A) which faces the (2-1)-th constant voltage electrode CVE2-1. The (2-1)-th cladding layer CLD2-1 may cover at least a (2-1)-th side surface portion S2-1 of the (2-1)-th constant voltage electrode CVE2-1 (see FIG. 29A) which faces the (1-1)-th constant voltage electrode CVE1-1. The (1-2)-th cladding layer CLD1-2 and the (2-1)-th cladding layer CLD2-1 may be a pattern included in the second via insulating layer VIA2 of FIG. 18.

In an embodiment, the (2-1)-th cladding layer CLD2-1 may include an opening OP exposing at least a portion of the upper surface of the (2-1)-th constant voltage electrode CVE2-1. As shown of FIG. 26, only one opening OP may be defined or a plurality of openings OP may be defined on the (2-1)-th constant voltage electrode CVE2-1.

Referring to FIG. 28A, the (1-2)-th constant voltage electrode CVE1-2 may have a stack structure of the first metal layer ML1, the second metal layer ML2, and the third metal layer ML3. The second metal layer ML2 may include a material having a relatively low electrical resistance compared to the first and third metal layers ML1 and ML3. For example, the second metal layer ML2 may include aluminum, and the first and third metal layers ML1 and ML3 may include titanium. Here, the first to third metal layers ML1, ML2, and ML3 forming the (1-2)-th side surface portion S1-2 of the (1-2)-th constant voltage electrode CVE1-2 may be covered by the (1-2)-th cladding layer CLD1-2.

Referring to FIG. 28B, in another embodiment, a side surface of a second metal layer ML2′ may be recessed from a side surface of a first metal layer ML1′ and a side surface of a third metal layer ML3′. Accordingly, an undercut structure as shown of FIG. 28B may be formed. This may be a structure formed by a difference of an etching rate of a material included in the second metal layer ML2′ and a material included in the first metal layer ML1′ and the third metal layer ML3′ in a formation process of the (1-2)-th constant voltage electrode CVE1-2. Also in this case, the first to third metal layers ML1′, ML2′, and ML3′ forming a (1-2)-th side surface portion S1-2′ of the (1-2)-th constant voltage electrode CVE1-2 may be covered by the (1-2)-th cladding layer CLD1-1.

Referring to FIG. 29A, the (2-1)-th constant voltage electrode CVE2-1 may also have a stack structure of a first metal layer ML1, a second metal layer ML2, and a third metal layer ML3. Here, the first to third metal layers ML1, ML2, ML3 forming the (2-1)-th side surface portion S2-1 of the (2-1)-th constant voltage electrode CVE2-1 may be covered by the (2-1)-th cladding layer CLD2-1.

Referring to FIG. 29B, in another embodiment, the side surface of the second metal layer ML2′ may be recessed from the side surface of the first metal layer ML1′ and the side surface of the third metal layer ML3′. Accordingly, an undercut structure as shown in FIG. 29B may be formed. This may be a structure formed by a difference of an etching rate of the material included in the second metal layer ML2′ and the material included in the first metal layer ML1′ and the third metal layer ML3′ in a formation process of the (2-1)-th constant voltage electrode CVE2-1. Also in this case, the first to third metal layers ML1′, ML2′, and ML3′ configuring a (2-1)-th side surface portion S2-1′ of the (2-1)-th constant voltage electrode CVE2-1 may be covered by the (2-1)-th cladding layer CLD2-1.

Referring to FIGS. 30 and 31, a (1-3)-th constant voltage electrode CVE1-3 and a (2-2)-th constant voltage electrode CVE2-2 may be disposed on the second via insulating layer VIA2. The (2-2)-th constant voltage electrode CVE2-2 may be disposed to be spaced apart from the (1-3)-th constant voltage electrode CVE1-3 in the first direction DR1. The (1-3)-th constant voltage electrode CVE1-3 may be the first constant voltage electrode CVE1 of FIG. 20, and the (2-2)-th constant voltage electrode CVE2-2 may be the second constant voltage electrode CVE2 of FIG. 20. The (1-3)-th constant voltage electrode CVE1-3 and the (2-2)-th constant voltage electrode CVE2-2 may be a pattern included in the third SD conductive layer SD3 of FIG. 18.

The (1-3)-th constant voltage electrode CVE (1-3)-th may extend from an upper surface of the (1-2)-th cladding layer CLD1-2 in the direction opposite to the first direction DR1, and may be in direct contact with at least a portion of an upper surface of the (1-2)-th constant voltage electrode CVE1-2.

The (2-2)-th constant voltage electrode CVE2-2 may extend from an upper surface of the (2-1)-th cladding layer CLD2-1 in the first direction DR1, and may be in direct contact with at least a portion of the upper surface of the (2-1)-th constant voltage electrode CVE2-1.

In an embodiment, when the (2-1)-th cladding layer CLD2-1 includes the opening OP of FIG. 27 exposing at least a portion of the upper surface of the (2-1)-th constant voltage electrode CVE2-1, the (2-2)-th constant voltage electrode CVE2-2 may directly contact the upper surface of the (2-1)-th constant voltage electrode CVE2-1 exposed by the opening OP of FIG. 27.

Referring to FIGS. 32 and 33, a second organic layer OIL2 and a third organic layer OIL3 may be disposed on the third SD conductive layer SD3. The second organic layer OIL2 and the third organic layer OIL3 may be a pattern included in the third via insulating layer VIA3 of FIG. 18.

The second organic layer OIL2 may be disposed on the (1-1)-th constant voltage electrode CVE1-1. According to an embodiment, at least a portion of the (1-2)-th constant voltage electrode CVE1-2 and/or at least a portion of the (1-3)-th constant voltage electrode CVE1-3 may be interposed between the second organic layer OIL2 and the (1-1)-th constant voltage electrode CVE1-1.

The third organic layer OIL3 may be disposed on the (2-2)-th constant voltage electrode CVE2-2.

Referring to FIGS. 34 and 35, an organic cover layer OCL, a fourth organic layer OIL4, and a fifth organic layer OIL5 may be disposed on the third SD conductive layer SD3. The organic cover layer OCL, the fourth organic layer OIL4, and the fifth organic layer OIL5 may be a pattern included in the pixel defining layer PDL of FIG. 19.

The fourth organic layer OIL4 may cover at least a portion of the second organic layer OIL2. A portion of the second organic layer OIL2 and the fourth organic layer OIL4 may form the second dam structure DAM2 described with reference to FIG. 1A. The second dam structure DAM2 may serve to block the organic encapsulation layer EN2.

The organic cover layer OCL may be disposed to be spaced apart from the fourth organic layer OIL4 in the first direction DR1. The organic cover layer OCL may cover at least a portion of the (1-2)-th cladding layer CLD1-2. According to embodiments, the organic cover layer OCL may entirely cover the (1-2)-th cladding layer CLD1-2.

A spacer pattern SPC may be disposed on the organic cover layer OCL. The spacer pattern SPC may include an organic insulating material and/or an inorganic insulating material.

The (1-2)-th cladding layer CLD1-2, the organic cover layer OCL, and the spacer pattern SPC may form the first dam structure DAM1 described with reference to FIG. 1A. The first dam structure DAM1 may be disposed to block the organic encapsulation layer EN2 that is not blocked by the second dam structure DAM2.

The fifth organic layer OIL5 may be disposed to be spaced apart from the organic cover layer OCL in the first direction DR1. The fifth organic layer OIL5 may entirely cover the (2-1)-th cladding layer CLD2-1, the (2-2)-th constant voltage electrode CVE2-2, and the third organic layer OIL3.

As described above, the organic encapsulation layer EN2 may be blocked by the second dam structure DAM2. In this case, the first inorganic encapsulation layer EN1 and the second inorganic encapsulation layer EN3 may contact each other on an upper surface of the second dam structure DMA2. In addition, the first inorganic encapsulation layer EN1 and the second inorganic encapsulation layer EN3 may also be disposed on the fifth organic layer OIL5 by extending in the direction opposite to the first direction DR1 from an upper surface of the second dam structure DAM2 in a state in which the first inorganic encapsulation layer EN1 and the second inorganic encapsulation layer EN3 are in contact with each other.

Here, in an area between the (1-1)-th constant voltage electrode CVE1-1 and the (2-1)-th constant voltage electrode CVE2-1, the first inorganic encapsulation layer EN1 and the second inorganic encapsulation layer EN3 may be in contact with each other. A CVD area CVD in which an organic insulating material is not interposed between the connection electrode CNE and the first inorganic encapsulation layer EN1 may be defined.

Referring to FIGS. 23A and 35 again, the (1-1)-th side surface portion S1-1 of the (1-1)-th constant voltage electrode CVE1-1 may be covered by the (1-1)-th cladding layer CLD1-1. The (1-1)-th cladding layer CLD1-1 may protect the (1-1)-th side surface portion S1-1 of the (1-1)-th constant voltage electrode CVE1-1 when forming the (1-2)-th constant voltage electrode CVE1-2. Accordingly, the (1-1)-th side surface portion S1-1, which is relatively vulnerable to damage, may not be substantially damaged when forming the (1-2)-th constant voltage electrode CVE1-2, and thus reliability of the first constant voltage electrode CVE1 including the (1-1)-th constant voltage electrode CVE1-1 may be improved.

Referring to FIGS. 23B and 35 again, even in a case where the undercut structure as shown of FIG. 23B is formed, the (1-1)-th side surface portion S1-1′ of the (1-1)-th constant voltage electrode CVE1-1 may be covered by the (1-1)-th cladding layer CLD1-1. Here, as the above-described undercut structure is covered by the (1-1)-th cladding layer CLD1-1, reliability of other elements disposed on the (1-1)-th cladding layer CLD1-1 covering the (1-1)-th side surface portion S1-1′ of the (1-1)-th constant voltage electrode CVE1-1 may be sufficiently secured. That is, a problem such as disconnection of the other elements due to the above-described undercut structure may not substantially occur.

Referring to FIGS. 28A and 35 again, the (1-2)-th side surface portion S1-2 of the (1-2)-th constant voltage electrode CVE1-2 may be covered by the (1-2)-th cladding layer CLD1-2. The (1-2)-th cladding layer CLD1-2 may serve to protect the (1-2)-th side surface portion S1-2 of the (1-2)-th constant voltage electrode CVE1-2 during a formation process of forming the (1-3)-th constant voltage electrode CVE1-3. Accordingly, the (1-2)-th side surface portion S1-2, which is relatively vulnerable to damage, may not be substantially damaged during the formation process, and thus reliability of the first constant voltage electrode CVE1 including the (1-2)-th constant voltage electrode CVE1-2 may be improved.

Referring to FIGS. 28B and 35 again, even in a case where the undercut structure as shown of FIG. 28B is formed, the (1-2)-th side surface portion S1-2′ of the (1-2)-th constant voltage electrode CVE1-2 may be covered by the (1-2)-th cladding layer CLD1-2. Here, as the above-described undercut structure is covered by the (1-2)-th cladding layer CLD1-2, reliability of other elements disposed on the (1-2)-th cladding layer CLD1-2 covering the (1-2)-th side surface portion S1-2′ of the (1-2)-th constant voltage electrode CVE1-2 may be sufficiently secured.

Referring to FIGS. 29A and 35 again, the (2-1)-th side surface portion S2-1 of the (2-1)-th constant voltage electrode CVE2-1 may be covered by the (2-1)-th cladding layer CLD2-1. The (2-1)-th cladding layer CLD2-1 may serve to protect the (2-1)-th side surface portion S2-1 of the (2-1)-th constant voltage electrode CVE2-1 when forming the (2-2)-th constant voltage electrode CVE2-2. Accordingly, the (2-1)-th side surface portion of the (2-1)-th constant voltage electrode CVE2-1, which is relatively vulnerable to damage, may not be substantially damaged when forming the (2-2)-th constant voltage electrode CVE2-2, and thus reliability of the second constant voltage electrode CVE2 including the (2-1)-th constant voltage electrode CVE2-1 may be improved.

Referring to FIGS. 29B and 35 again, even in a case where the undercut structure as shown of FIG. 29B is formed, the (2-1)-th side surface portion S2-1′ of the (2-1)-th constant voltage electrode CVE2-1 may be covered by the (2-1)-th cladding layer CLD2-1. Here, as the above-described undercut structure is covered by the (2-1)-th cladding layer CLD2-1, reliability of other elements disposed on the (2-1)-th cladding layer CLD2-1 covering the (2-1)-th side surface portion S2-1′ of the (2-1)-th constant voltage electrode CVE2-1 may be sufficiently secured.

Referring to FIG. 35, the (1-3)-th side surface portion disposed on the (1-2)-th cladding layer CLD1-2 among the side surface portions of the (1-3)-th constant voltage electrode CVE1-3 may be covered by the organic cover layer OCL. Accordingly, reliability of other elements disposed on the organic cover layer OCL covering the (1-3)-th side surface portion of the (1-3)-th constant voltage electrode CVE1-3 may be sufficiently secured. For example, even in a case where the (1-3)-th constant voltage electrode CVE1-3 has the stack structure of the first to third metal layers ML1′, ML2′, and ML3′ described with reference to FIG. 23B or 28B and the (1-3)-th side surface portion has the undercut structure described with reference to FIG. 23B or 28B, sufficient reliability may be secured.

Referring to FIG. 35 again, a side surface portion of the (2-2)-th constant voltage electrode CVE2-2 may be covered by the fifth organic layer OIL5. Accordingly, reliability of other elements disposed on the fifth organic layer OIL5 the side surface portion of the (2-2)-th constant voltage electrode CVE2-2 may be sufficiently secured. For example, even in a case where the (2-2)-th constant voltage electrode CVE2-2 has the stack structure of the first to third metal layers ML1′, ML2′, and ML3′ described with reference to FIG. 29B and the side surface portion of the (2-2)-th constant voltage electrode CVE2-2 has the undercut structure described with reference to FIG. 29B, sufficient reliability may be secured.

Although the disclosure is described with reference to the above embodiments, those skilled in the art will understand that the disclosure may be variously corrected and changed without departing from the spirit and scope of the disclosure as set forth in the claims below.

What is claimed is:

1. A display device comprising:
a plurality of pixels disposed in a display area;
a (1-1)-th constant voltage electrode disposed in a peripheral area;
a (2-1)-th constant voltage electrode disposed in the peripheral area to be spaced apart from the (1-1)-th constant voltage electrode;
a connection electrode electrically connecting the (1-1)-th constant voltage electrode and the (2-1)-th constant voltage electrode, and disposed on a layer different from the (1-1)-th constant voltage electrode and the (2-1)-th constant voltage electrode in a cross-sectional view;
a (1-1)-th cladding layer covering at least a (1-1)-th side surface portion of the (1-1)-th constant voltage electrode facing the (2-1)-th constant voltage electrode; and
a (1-2)-th constant voltage electrode disposed on an upper surface of the (1-1)-th cladding layer and directly contacting at least a portion of an upper surface of the (1-1)-th constant voltage electrode.

2. The display device according to claim 1, further comprising:
a (1-2)-th cladding layer covering at least a (1-2)-th side surface portion of the (1-2)-th constant voltage electrode disposed on the (1-1)-th cladding layer.

3. The display device according to claim 2, further comprising:
an organic cover layer entirely covering the (1-2)-th cladding layer.

4. The display device according to claim 3, wherein the (1-1)-th cladding layer, the (1-2)-th cladding layer, and the organic cover layer form a first dam structure, and
the first dam structure surrounds the display area in a plan view.

5. The display device according to claim 4, further comprising:
a second dam structure disposed on the (1-1)-th constant voltage electrode in a cross-sectional view, and
wherein the second dam structure is disposed between the display area and the first dam structure to surround the display area in a plan view.

6. The display device according to claim 5, wherein the (1-2)-th constant voltage electrode is interposed between the second dam structure and the (1-1)-th constant voltage electrode in a cross-sectional view.

7. The display device according to claim 1, further comprising:
a (2-1)-th cladding layer covering at least a (2-1)-th side surface portion of the (2-1)-th constant voltage electrode facing the (1-1)-th constant voltage electrode; and
a (2-2)-th constant voltage electrode disposed on an upper surface of the (2-1)-th cladding layer and directly contacting at least a portion of an upper surface of the (2-1)-th constant voltage electrode.

8. The display device according to claim 7, wherein the (2-1)-th cladding layer entirely covers the side surface portion of the (2-1)-th constant voltage electrode.

9. The display device according to claim 8, wherein the (2-1)-th cladding layer includes an opening exposing at least a portion of an upper surface of the (2-1)-th constant voltage electrode, and
wherein the (2-2)-th constant voltage electrode directly contacts the upper surface of the (2-1)-th constant voltage electrode exposed by the opening.

10. The display device according to claim 9, wherein the opening is provided in plural.

11. The display device according to claim 1, further comprising:
an encapsulation layer entirely covering the plurality of pixels disposed in the display area,
wherein the encapsulation layer includes a first inorganic encapsulation layer, a second inorganic encapsulation layer, and an organic encapsulation layer interposed between the first inorganic encapsulation layer and the second inorganic encapsulation layer.

12. The display device according to claim 11, wherein the first inorganic encapsulation layer and the second inorganic encapsulation layer directly contact each other in an area between the (1-1)-th constant voltage electrode and the (2-1)-th constant voltage electrode in a plan view.

13. The display device according to claim 12, wherein a CVD area in which an organic insulating material is not interposed between the connection electrode and the first inorganic encapsulation layer is disposed in an area overlapping the connection electrode.

14. A display device comprising:
a plurality of pixels disposed in a display area;
a (1-1)-th constant voltage electrode disposed in a peripheral area;
a (2-1)-th constant voltage electrode disposed in the peripheral area to be spaced apart from the (1-1)-th constant voltage electrode;
a connection electrode electrically connecting the (1-1)-th constant voltage electrode and the (2-1)-th constant voltage electrode, and disposed on a layer different from the (1-1)-th constant voltage electrode and the (2-1)-th constant voltage electrode in a cross-sectional view;
a (1-1)-th cladding layer covering at least a (1-1)-th side surface portion of the (1-1)-th constant voltage electrode facing the (2-1)-th constant voltage electrode;
a (1-2)-th constant voltage electrode disposed on an upper surface of the (1-1)-th cladding layer and directly contacting at least a portion of an upper surface of the (1-1)-th constant voltage electrode;
a (1-2)-th cladding layer covering at least a (1-2)-th side surface portion of the (1-2)-th constant voltage electrode disposed on the (1-1)-th cladding layer; and
a (1-3)-th constant voltage electrode disposed on an upper surface of the (1-2)-th cladding layer and directly contacting at least a portion of an upper surface of the (1-2)-th constant voltage electrode.

15. The display device according to claim 14, further comprising:
an organic cover layer entirely covering the (1-2)-th cladding layer.

16. The display device according to claim 15, wherein the (1-2)-th cladding layer and the organic cover layer form a first dam structure, and
in a plan view, the first dam structure surrounds the display area.

17. The display device according to claim 14, further comprising:
a (2-1)-th cladding layer covering at least a (2-1)-th side surface portion of the (2-1)-th constant voltage electrode facing the (1-2)-th constant voltage electrode; and
a (2-2)-th constant voltage electrode disposed on an upper surface of the (2-1)-th cladding layer and directly contacting at least a portion of an upper surface of the (2-1)-th constant voltage electrode.

18. The display device according to claim 14, further comprising:
an encapsulation layer entirely disposed on the plurality of pixels disposed in the display area,
wherein the encapsulation layer includes a first inorganic encapsulation layer, a second inorganic encapsulation layer, and an organic encapsulation layer interposed between the first inorganic encapsulation layer and the second inorganic encapsulation layer.

19. The display device according to claim 18, wherein the first inorganic encapsulation layer and the second inorganic encapsulation layer directly contact each other in an area between the (1-1)-th constant voltage electrode and the (2-1)-th constant voltage electrode in a plan view.

20. The display device according to claim 19, wherein a CVD area in which an organic insulating material is not interposed between the connection electrode and the first inorganic encapsulation layer is disposed in an area overlapping the connection electrode.
